(19) United States
(12) Patent Application Publication
(10) Pub. No.: US 2026/0324218 A1
(43) Pub. Date: Oct. 15, 2026

(54) DISPLAY DEVICE AND ELECTRONIC DEVICE INCLUDING THE SAME

(71) Applicant: Samsung Display Co., Ltd., Yongin-si (KR)

(72) Inventors: Seung Jun LEE, Yongin-si (KR); Gun Hee KIM, Yongin-si (KR); Hyang A PARK, Yongin-si (KR)

(21) Appl. No.: 19/366,279

(22) Filed: Oct. 22, 2025

(30) Foreign Application Priority Data
Apr. 14, 2025 (KR) 10-2025-0047825

(51) Int. Cl. H10K 59/131; H10K 59/121

(52) U.S. Cl. CPC H10K 59/131; H10K 59/1213; H10K 59/1216

(57) ABSTRACT

A display device includes: a substrate; a bottom metal layer located on the substrate and comprising a first electrode of a first capacitor; a second semiconductor layer located on the bottom metal layer and comprising an active layer of a first transistor; and a third gate metal layer located on the second semiconductor layer and comprising a gate electrode of the first transistor. The active layer of the first transistor may comprise a first electrode of the first transistor, a second electrode of the first transistor, and a first channel portion located between the first electrode and the second electrode of the first transistor. The first electrode of the first capacitor may be electrically connected to the gate electrode of the first transistor.

### CROSS-REFERENCE TO RELATED APPLICATION

This application claims priority to and the benefit of Korean Patent Application No. 10-2025-0047825, filed on Apr. 14, 2025, in the Korean Intellectual Property Office, the entire disclosure of which is incorporated by reference herein.

### BACKGROUND

### 1. Field

The present specification relates to a display device and an electronic device including the same.

### 2. Description of the Related Art

Electroluminescence displays can be divided into inorganic light emitting displays and organic light emitting displays depending on the material of a light emitting layer. An active matrix type organic light emitting display includes an organic light emitting diode (OLED) that emits light by itself and has advantages of fast response speed, high luminous efficiency, high luminance and wide viewing angle. In the organic light emitting display, the OLED is formed in each pixel. The organic light emitting display not only has fast response speed and excellent luminous efficiency, luminance and viewing angle, but also has excellent contrast ratio and color gamut because it can express a black gray level as complete black.

### SUMMARY

An aspect of the present specification is to solve the problem of insufficient capacity of a storage capacitor caused by the application of a back-gate voltage.

However, aspects and features of embodiments of the present specification are not restricted to the one set forth herein. The above and other aspects and features of embodiments of the present specification will become more apparent to one of ordinary skill in the art to which the present specification pertains by referencing the detailed description of the present specification given below.

According to one or more embodiments of the present disclosure, a display device may comprise: a substrate; a bottom metal layer located on the substrate and comprising a first electrode of a first capacitor; a second semiconductor layer located on the bottom metal layer and comprising an active layer of a first transistor; and a third gate metal layer located on the second semiconductor layer and comprising a gate electrode of the first transistor. The active layer of the first transistor may comprise a first electrode of the first transistor, a second electrode of the first transistor, and a first channel portion located between the first electrode and the second electrode of the first transistor. The first electrode of the first capacitor may be electrically connected to the gate electrode of the first transistor.

According to one or more embodiments of the present disclosure, the display device may further comprise a first semiconductor layer located between the bottom metal layer and the second semiconductor layer and comprising a second electrode of the first capacitor. The second electrode of the first capacitor may be electrically connected to the first electrode of the first transistor, and the second electrode of the first capacitor may overlap the first electrode of the first capacitor in a thickness direction of the substrate.

According to one or more embodiments of the present disclosure, the display device may further comprise a first gate metal layer located between the first semiconductor layer and the second semiconductor layer and comprising a first electrode of a second capacitor. The first electrode of the second capacitor may be electrically connected to the gate electrode of the first transistor, and the first electrode of the second capacitor may overlap the second electrode of the first capacitor in the thickness direction of the substrate.

According to one or more embodiments of the present disclosure, the display device may further comprise a first semiconductor layer located between the bottom metal layer and the second semiconductor layer and comprising a second electrode of the first capacitor, and a second gate metal layer located between the first semiconductor layer and the second semiconductor layer and comprising a second electrode of a third capacitor. The second electrode of the third capacitor may be electrically connected to the first electrode of the first transistor.

According to one or more embodiments of the present disclosure, the second electrode of the first capacitor may be electrically connected to the second electrode of the third capacitor.

According to one or more embodiments of the present disclosure, the third gate metal layer may further comprise a first connection electrode. The first connection electrode may be electrically connected to the second electrode of the first capacitor and the second electrode of the third capacitor.

According to one or more embodiments of the present disclosure, the second semiconductor layer may further comprise a first electrode of the third capacitor and a first electrode of a fourth capacitor. A first driving voltage may be applied to the first electrode of the third capacitor and the first electrode of the fourth capacitor. The second electrode of the third capacitor may overlap the first electrode of the third capacitor in a thickness direction of the substrate, and the second electrode of the third capacitor may overlap the first electrode of the fourth capacitor in the thickness direction of the substrate.

According to one or more embodiments of the present disclosure, the display device may further comprise a first gate metal layer located between the first semiconductor layer and the second gate metal layer and comprising a first electrode of a fifth capacitor. A first driving voltage may be applied to the first electrode of the fifth capacitor, and the second electrode of the third capacitor may overlap the first electrode of the fifth capacitor in the thickness direction of the substrate.

According to one or more embodiments of the present disclosure, the second electrode of the first capacitor may overlap the first electrode of the fifth capacitor in the thickness direction of the substrate.

According to one or more embodiments of the present disclosure, the display device may further comprise a first semiconductor layer located between the bottom metal layer and the second semiconductor layer and comprising an active layer of a fifth transistor. The active layer of the fifth transistor may further comprise a first electrode of the fifth transistor to which a first driving voltage is applied, a second electrode of the fifth transistor, and a fifth channel portion located between the first electrode and the second electrode of the fifth transistor. The bottom metal layer may further comprise a fifth bottom metal layer overlapping the fifth channel portion in a thickness direction of the substrate.

According to one or more embodiments of the present disclosure, the second electrode of the fifth transistor may be electrically connected to the second electrode of the first transistor through a plurality of contact holes.

According to one or more embodiments of the present disclosure, the first semiconductor layer may further comprise a first electrode of a fifth capacitor, and the first electrode of the fifth transistor may be electrically connected to the first electrode of the fifth capacitor through a plurality of contact holes.

According to one or more embodiments of the present disclosure, the display device may further comprise a first semiconductor layer located between the bottom metal layer and the second semiconductor layer, and a second gate metal layer located between the first semiconductor layer and the second semiconductor layer and comprising a bottom gate electrode of the first transistor. The bottom gate electrode of the first transistor may overlap the active layer of the first transistor in a thickness direction of the substrate.

According to one or more embodiments of the present disclosure, the gate electrode of the first transistor is configured to supply a first gate voltage to the first transistor, and the bottom gate electrode of the first transistor is configured to supply a second gate voltage to the first transistor.

According to one or more embodiments of the present disclosure, a third driving voltage is applied to the bottom gate electrode of the first transistor which is configured to supply the second gate voltage, and a driving current curve of the first transistor shifts as the third driving voltage is changed.

According to one or more embodiments of the present disclosure, an electronic device may comprise: a processor configured to provide an image signal; a display module configured to receive the image signal from the processor and displaying an image; and a power module configured to supply power to the display module. The display module may comprise: a substrate; a bottom metal layer located on the substrate and comprising a first electrode of a first capacitor; a second semiconductor layer located on the bottom metal layer and comprising an active layer of a first transistor; and a third gate metal layer located on the second semiconductor layer and comprising a gate electrode of the first transistor. The active layer of the first transistor may comprise a first electrode of the first transistor, a second electrode of the first transistor, and a first channel portion located between the first electrode and the second electrode of the first transistor. The first electrode of the first capacitor may be electrically connected to the gate electrode of the first transistor.

According to one or more embodiments of the present disclosure, the electronic device may further comprise a first semiconductor layer located between the bottom metal layer and the second semiconductor layer and comprising a second electrode of the first capacitor. The second electrode of the first capacitor may be electrically connected to the first electrode of the first transistor, and may overlap the first electrode of the first capacitor in the thickness direction of the substrate.

According to one or more embodiments of the present disclosure, the electronic device may further comprise a first semiconductor layer located between the bottom metal layer and the second semiconductor layer and comprising a second electrode of the first capacitor, and a second gate metal layer located between the first semiconductor layer and the second semiconductor layer and comprising a second electrode of a third capacitor. The second electrode of the third capacitor may be electrically connected to the first electrode of the first transistor.

According to one or more embodiments of the present disclosure, the electronic device may further comprise a first semiconductor layer located between the bottom metal layer and the second semiconductor layer and comprising an active layer of a fifth transistor. The active layer of the fifth transistor may further comprise a first electrode of the fifth transistor to which a first driving voltage is applied, a second electrode of the fifth transistor, and a fifth channel portion located between the first electrode and the second electrode of the fifth transistor. The bottom metal layer may further comprise a fifth bottom metal layer overlapping the fifth channel portion in a thickness direction of the substrate.

According to one or more embodiments of the present disclosure, the electronic device may further comprise a first semiconductor layer located between the bottom metal layer and the second semiconductor layer, and a second gate metal layer located between the first semiconductor layer and the second semiconductor layer and comprising a bottom gate electrode of the first transistor. The bottom gate electrode of the first transistor may overlap the active layer of the first transistor in a thickness direction of the substrate.

According to the present specification, it is possible to solve the problem of insufficient capacity of a first group capacitor due to a second gate metal layer separated to apply a second gate voltage to a first transistor.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of an electronic device according to one or more embodiments of the present specification;

FIG. 2 is an exploded perspective view of the electronic device according to one or more embodiments of the present specification;

FIG. 3 is a plan view of a display device of FIG. 2;

FIG. 4 is a cross-sectional view taken along the line A-A′ of FIG. 3;

FIG. 5 is a plan view of a portion B of FIG. 3;

FIG. 6 is a block diagram of the display device of FIG. 2;

FIG. 7 is an equivalent circuit diagram of a conventional pixel circuit;

FIG. 8 is a plan view of a circuit layer included in a subpixel according to one or more embodiments of the present disclosure;

FIG. 9 is a modified circuit diagram illustrating the connection relationship between a plurality of layers in the circuit layer included in the subpixel according to one or more embodiments of the present disclosure, together with a plurality of contact holes;

FIG. 10 illustrates a notation method for explaining the connection relationship between a plurality of layers and a contact hole disclosed in the present disclosure;

FIGS. 11 and 12 are a plan view and a modified circuit diagram illustrating a bottom metal layer and contact holes related to the bottom metal layer in the subpixel according to one or more embodiments of the present specification;

FIGS. 13 and 14 are a plan view and a modified circuit diagram illustrating a first semiconductor layer and contact holes related to the first semiconductor layer in the subpixel according to one or more embodiments of the present disclosure;

FIGS. 15 and 16 are a plan view and a modified circuit diagram illustrating a first gate metal layer and contact holes related to the first gate metal layer in the subpixel according to one or more embodiments of the present disclosure;

FIGS. 17 and 18 are a plan view and a modified circuit diagram illustrating a second gate metal layer and contact holes related to the second gate metal layer in the subpixel according to one or more embodiments of the present disclosure;

FIGS. 19 and 20 are a plan view and a modified circuit diagram illustrating a second semiconductor layer and contact holes related to the second semiconductor layer in the subpixel according to one or more embodiments of the present disclosure;

FIGS. 21 and 22 are a plan view and a modified circuit diagram illustrating a third gate metal layer and contact holes related to the third gate metal layer in the subpixel according to one or more embodiments of the present specification;

FIGS. 23, 24, and 25 are plan views and a modified circuit diagram illustrating a first connection metal layer and contact holes related to the first connection metal layer in the subpixel according to one or more embodiments of the present specification;

FIG. 26 is a cross-sectional view taken along the line I-I′ of FIG. 8;

FIG. 27 is a cross-sectional view taken along the line II-II′ of FIG. 8;

FIG. 28 is a cross-sectional view taken along the line III-III′ of FIG. 8;

FIG. 29 is a cross-sectional view taken along the line IV-IV′ of FIG. 8;

FIG. 30 is a cross-sectional view taken along the line V-V′ of FIG. 8;

FIG. 31 is a graph illustrating the change in driving current according to the application of a back-gate voltage to a first transistor;

FIG. 32 is a block diagram of an electronic device according to one or more embodiments of the present specification; and

FIG. 33 is a schematic diagram of electronic devices according to various embodiments of the present specification.

### DETAILED DESCRIPTION

The aspects and features of embodiments disclosed herein, and methods of achieving them, will become apparent upon reference to embodiments described in detail with accompanying drawings. However, the present disclosure is not limited to embodiments disclosed herein, but will be embodied in many different forms, and these embodiments are provided merely to make the present disclosure complete and to fully inform one of ordinary skill in the art to which the present disclosure belongs, and the present disclosure may be defined by the scope of the claims and their equivalents.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those shown herein.

Although first, second, and/or the like are used to describe various components, the components are not limited by these terms. Thus, a first component referred to herein may also be a second component within the technical idea of the present disclosure.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

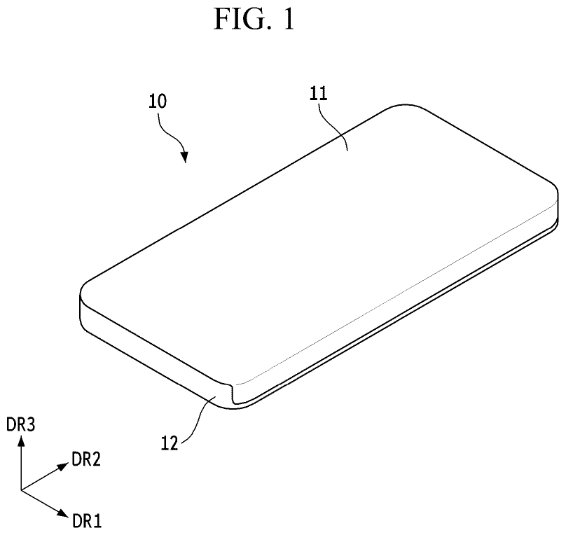

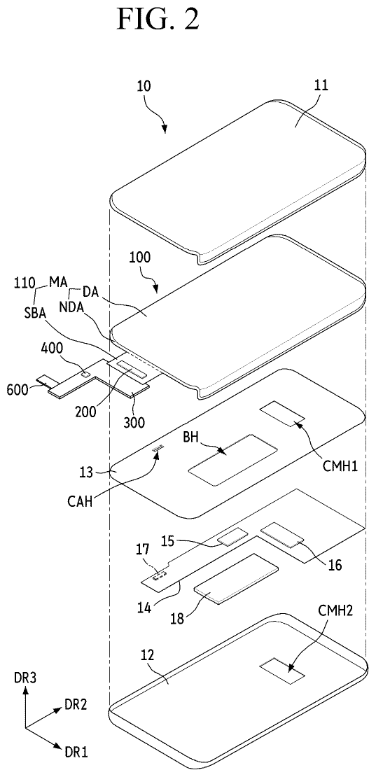

FIG. 1 is a perspective view of an electronic device 10 according to one or more embodiments of the present specification. FIG. 2 is an exploded perspective view of the electronic device 10 according to one or more embodiments of the present specification.

Referring to FIG. 1, the electronic device 10 according to one or more embodiments is a device having a function of displaying an image in a display area. The electronic device 10 may be portable. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).

However, the electronic device 10 according to the embodiment is not limited to a portable electronic device and may also be a large-sized device such as a television, a notebook computer, a monitor, a billboard, and/or an Internet of things (IOT) device.

The electronic device 10 according to one or more embodiments may include a cover window 11 and a bottom cover 12 provided as a housing to protect a display device.

Referring to FIG. 2, the electronic device 10 may further include a display device 100, a bracket 13, and a main circuit board 14 accommodated between the cover window 11 and the bottom cover 12.

The display device 100 may include a main area MA and a sub-area SBA protruding from a side of the main area MA. The main area MA may include a display area DA, in which image display is implemented, and a non-display area NDA around the display area DA along an edge or a periphery of the display area DA.

The display device 100 may further include a display driving circuit 200 located in the sub-area SBA, a display circuit board 300 bonded to a side of the sub-area SBA, a touch driving circuit 400 mounted on the display circuit board 300, and a cable 600 extending from a side of the display circuit board 300.

In the present specification, a first direction DR1 may be a direction parallel to short sides of the electronic device 10 in a plan view, that is, a horizontal direction of the electronic device 10. A second direction DR2 may be a direction parallel to long sides of the electronic device 10 in a plan view, that is, a vertical direction of the electronic device 10. A third direction DR3 may be a thickness direction of the electronic device 10.

The electronic device 10 may have a shape close to a rectangle in a plan view. For example, the electronic device 10 may have a rectangular planar shape having short sides in the first direction DR1 and long sides in the second direction DR2. Each corner where a short side extending in the first direction DR1 meets a long side extending in the second direction DR2 may be rounded to have a suitable curvature (e.g., a selected curvature) or may be right-angled. The planar shape of the electronic device 10 is not limited to a rectangular shape but may also be other polygonal shapes, a circular shape, or an oval shape.

The cover window 11 may be placed on the display device 100 to cover an upper surface of the display device 100. The cover window 11 may serve to protect the upper surface of the display device 100. The cover window 11 may include a light transmitting portion that is transparent and a light blocking portion that is opaque. The light transmitting portion may overlap the display area DA of the display device 100 in the third direction DR3, and the light blocking portion may overlap the non-display area NDA of the display device 100 in the third direction DR3.

The cover window 11 may include an upper surface portion that forms an upper surface of the electronic device 10, a left side surface portion that forms a left side surface of the electronic device 10, and a right side surface portion that forms a right side surface of the electronic device 10. The left side surface portion of the cover window 11 may extend from a left side of the upper surface portion, and the right side surface portion may extend from a right side of the upper surface portion.

Each of the upper surface portion, the left side surface portion, and the right side surface portion of the cover window 11 may include a light transmitting portion and a light blocking portion.

The light transmitting portion of the cover window 11 may be located in most of each of the upper surface portion, the left side surface portion, and the right side surface portion of the cover window 11.

The light blocking portion of the cover window 11 may be located at an upper edge and lower edge of the upper surface portion of the cover window 11, at an upper edge, left edge and lower edge of the left side surface portion of the cover window 11, and at an upper edge, right edge and lower edge of the right side surface portion of the cover window 11.

The display device 100 may be located under the cover window 11.

That is, the cover window 11 may be located on the display device 100.

The display device 100 may include an upper surface portion facing the upper surface portion of the cover window 11, a left side surface portion facing the left side surface portion of the cover window 11, and a right side surface portion facing the right side surface portion of the cover window 11. The left side surface portion of the display device 100 may extend from a left side of the upper surface portion, and the right side surface portion may extend from a right side of the upper surface portion.

The display device 100 may include the main area MA that serves as a display surface and the sub-area SBA that protrudes from at least a portion of a side of the main area MA.

The main area MA may include the display area DA that displays an image and the non-display area NDA around the display area DA.

The display area DA may be located in most of the main area MA. The display area DA may be located in the center of the main area MA.

In other words, each of the upper surface portion, the left side surface portion, and the right side surface of the display device 100 may include the display area DA and the non-display area NDA.

The display area DA may be located in most of each of the upper surface portion, the left side surface portion, and the right side surface portion of the display device 100.

The non-display area NDA may be located outside the display area DA. The non-display area NDA may be an edge area of the main area MA.

The non-display area NDA may be located at an upper edge and lower edge of the upper surface portion of the display device 100, at an upper edge, left edge, and lower edge of the left side surface portion of the display device 10, and at an upper edge, right edge, and lower edge of the right side surface portion of the display device 100.

The sub-area SBA may protrude from a side of the main area MA in the second direction DR2.

A length of the sub-area SBA in the first direction DR1 may be equal to or smaller than a length of the main area MA in the first direction DR1. A length of the sub-area SBA in the second direction DR2 may be smaller than a length of the main area MA in the second direction DR2, but the present disclosure is not limited to this case.

As a portion of the sub-area SBA is changed into a bent shape, the other portion of the sub-area SBA may be overlapped by the main area MA in the third direction DR3.

The display driving circuit 200 may be mounted on the sub-area SBA, and the display circuit board 300 may be attached to the sub-area SBA.

An end of the display circuit board 300 may be attached onto pads located at a lower edge of the sub-area SBA of the display device 100 using an anisotropic conductive film.

The display circuit board 300 may be a flexible printed circuit board (FPCB) that can be bent, a rigid printed circuit board that maintains a flat shape, or a composite printed circuit board including both a rigid printed circuit board and a flexible printed circuit board.

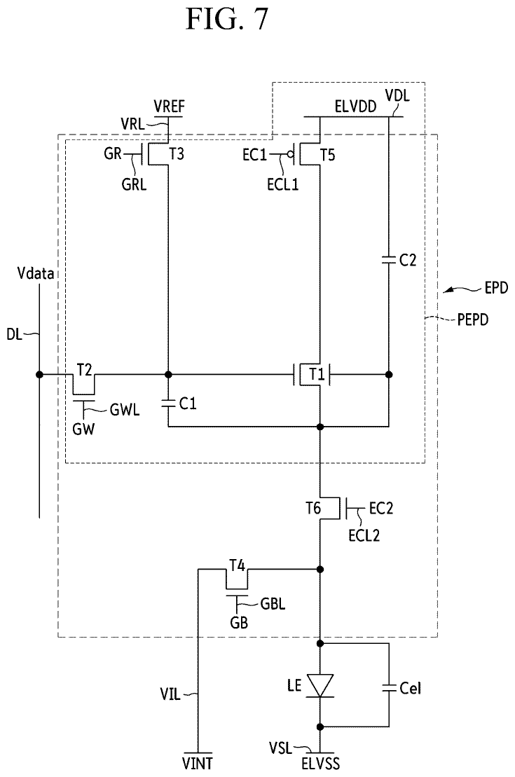

The display driving circuit 200 may transmit respective data signals Vdata (see FIG. 7) of pixel circuits EPD (see FIG. 7) of the display area DA to data lines DL (see FIG. 7) based on control signals, powers, and voltages supplied through the display circuit board 300.

The display driving circuit 200 may be provided as an integrated circuit and may be mounted on the sub-area SBA of the display device 100 using a chip on glass (COG) method, a chip on plastic (COP) method, or an ultrasonic method. However, this is merely an example, and the present disclosure is not limited to this example. For example, the display driving circuit 200 may also be mounted on the display circuit board 300.

According to one or more embodiments, the touch driving circuit 400 may be further mounted on the sub-area SBA of the display device 100. Alternatively, the touch driving circuit 400 may be mounted on the display circuit board 300.

The touch driving circuit 400 may be electrically connected to a touch sensor layer of the display device 100.

The bracket 13 may be located under the display device 100. The bracket 13 may include plastic and/or metal. The bracket 13 may include a first camera hole CMH1 into which a camera device 16 is inserted, a battery hole BH in which a battery 18 is placed, and a cable hole CAH through which the cable 600 connected to the display circuit board 300 passes.

The main circuit board 14 and the battery 18 may be located under the bracket 13.

The main circuit board 14 may be a printed circuit board (PCB) or a flexible printed circuit board (FPCB).

The main circuit board 14 may include a main processor 15, the camera device 16, and a main connector 17. The main processor 15 may be formed as an integrated circuit (IC).

The camera device 16 may be located on both an upper surface and a lower surface of the main circuit board 14. The main processor 15 may be located on the upper surface of the main circuit board 14, and the main connector 17 may be located on the lower surface of the main circuit board 14.

The main processor 15 may control all functions of the electronic device 10.

For example, the main processor 15 may output digital video data to the display driving circuit 200 through the display circuit board 300 so that the display device 100 can display an image. In addition, the main processor 15 may receive touch data including a user's touch coordinates from the touch driving circuit 400, determine whether the user has touched or is in proximity, and then perform an operation corresponding to the user's touch input or proximity input. For example, the main processor 15 may execute an application or perform an operation indicated by an icon touched by the user.

The main processor 15 may be an application processor, a central processing unit, or a system chip formed as an integrated circuit.

The camera device 16 processes an image frame such as a still image and/or a moving image obtained by an image sensor in a camera mode and outputs the processed image frame to the main processor 15.

The cable 600 passing through the cable hole CAH of the bracket 13 may be connected to the main connector 17. Accordingly, the main circuit board 14 may be electrically connected to the display circuit board 300.

The battery 18 may not overlap the main circuit board 14 in the third direction DR3. The battery 18 may overlap the battery hole BH of the bracket 13 in the third direction DR3.

In addition, the main circuit board 14 may be further equipped with a mobile communication module that can transmit and receive wireless signals to and from at least one of a base station, an external terminal, or a server over a mobile communication network. The wireless signals may include voice signals, video call signals, and/or various types of data resulting from transmission and/or reception of text and/or multimedia messages.

The bottom cover 12 may be located under the main circuit board 14 and the battery 18. The bottom cover 12 may be fastened and fixed to the bracket 13. The bottom cover 12 may form an upper side surface, a lower side surface, and a lower surface of the electronic device 10. The bottom cover 12 may include plastic, metal, or both plastic and metal.

The bottom cover 12 may include a second camera hole CMH2, which exposes a lower surface of the camera device 16. The position of the camera device 16 and the positions of the first camera hole CMH1 and the second camera hole CMH2 corresponding to the camera device 16 are not limited to those illustrated in the drawing.

Next, a display device 100 according to one or more embodiments will be described.

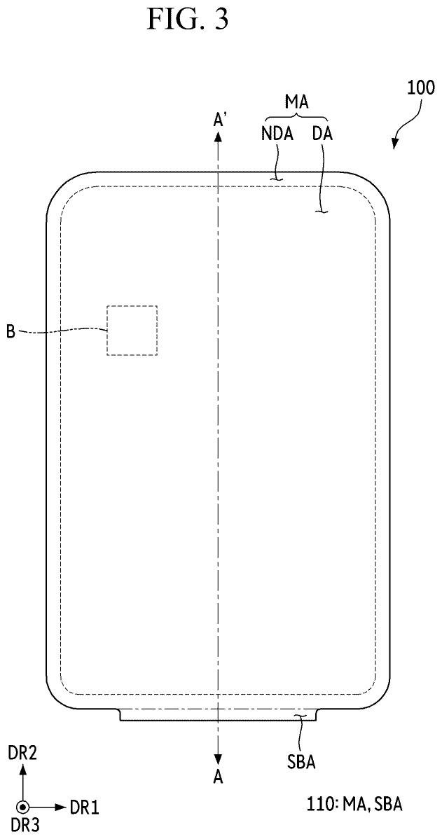

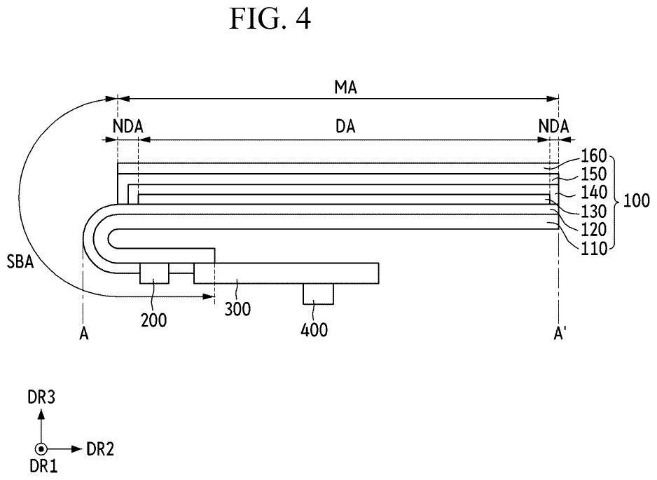

FIG. 3 is a plan view of the display device 100 of FIG. 2. FIG. 4 is a cross-sectional view taken along the line A-A′ of FIG. 3.

Referring to FIGS. 3 and 4, a display device 100 according to one or more embodiments is a device for displaying moving images and/or still images. The display device 100 may be used as a display screen in portable electronic devices such as mobile phones, smartphones, tablet PCs, smart watches, watch phones, mobile communication terminals, electronic notebooks, electronic books, PMPs, navigation devices and UMPCs, as well as in various products such as televisions, notebook computers, monitors, billboards, and/or IoT devices.

The display device 100 may be a light emitting display device such as an organic light emitting display device using an organic light emitting diode, a quantum dot light emitting display device including a quantum dot light emitting layer, an inorganic light emitting display device including an inorganic semiconductor, or a micro-or nano-light emitting display device using a micro-or nano-light emitting diode. A case where the display device 100 is an organic light emitting display device will be mainly described below. However, the present disclosure is not limited to this case. The present disclosure is also applicable to display devices including an organic insulating material, an organic light emitting material, and/or a metal material.

The display device 100 may be formed flat, but the present disclosure is not limited to this case. For example, the display device 100 may include a curved portion formed at left and right ends and having a constant or varying curvature. In addition, the display device 100 may be formed to be flexible so that it can be curved, bent, folded, and/or rolled.

Referring to FIG. 3, at least a surface of the display device 100 includes the main area MA, which emits light for image display.

The display area DA may be shaped like a rectangular plane having short sides in the first direction DR1 and long sides in the second direction DR2 intersecting the first direction DR1. Each corner where a short side extending in the first direction DR1 meets a long side extending in the second direction DR2 may be rounded to have a selected curvature or may be right-angled. The planar shape of the display area DA is not limited to a quadrangular shape but may also be other polygonal shapes, a circular shape, or an oval shape.

The display area DA may be located in most of the main area MA. The display area DA may be located in the center of the main area MA.

Referring to FIG. 4, the display device 100 may further include the sub-area SBA protruding in the second direction DR2 from at least a portion of a side of the main area MA.

As a portion of the sub-area SBA is changed into a bent shape, the other portion of the sub-area SBA may be placed on a back surface of the display device 100.

According to one or more embodiments, the display device 100 includes a substrate 110, a circuit layer 120 located on the substrate 110, and an element layer 130 located on the circuit layer 120.

The display device 100 may further include a sealing layer 140 located on the element layer 130 and a touch sensor layer 150 located on the sealing layer 140.

The display device 100 may further include a polarizing layer 160 located on the touch sensor layer 150 to reduce reflection of external light.

The substrate 110 may include the main area MA corresponding to the display surface and the sub-area SBA protruding in the second direction DR2 from at least a portion of a side of the main area MA.

The main area MA of the substrate 110 may include the display area DA for emitting light and the non-display area NDA located around the display area DA.

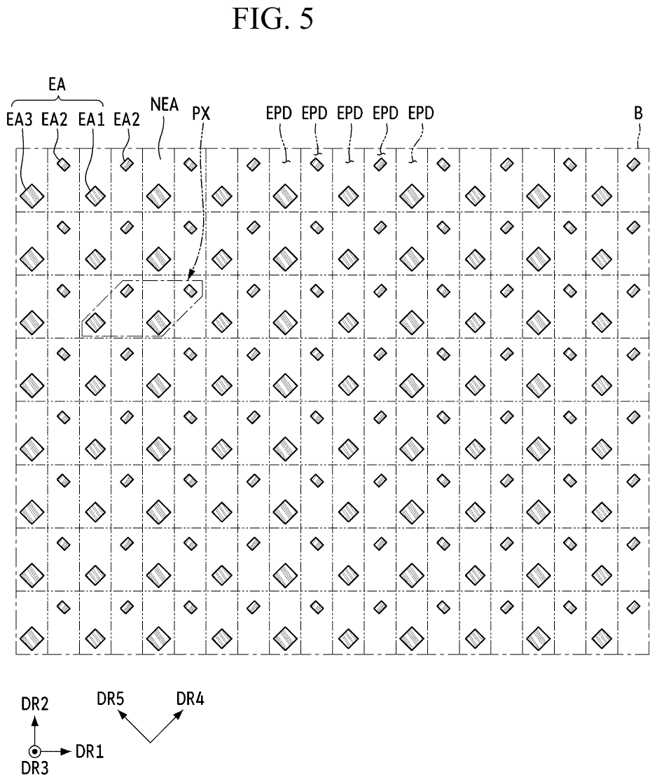

According to one or more embodiments, the element layer 130 may include light emitting elements LE (see FIG. 7) located in emission areas EA (see FIG. 5), respectively.

The circuit layer 120 may include pixel circuits EPD (see FIG. 5) electrically connected to the light emitting elements LE and one or more constant voltage lines transmitting one or more constant voltages to the pixel circuits EPD.

The constant voltage lines may include a first driving voltage line VDL (see FIG. 7) that transmits a first driving voltage ELVDD (see FIG. 7), a second power line VSL that transmits a second driving voltage ELVSS different from the first driving voltage ELVDD (see FIG. 7), an initialization voltage line VIL (see FIG. 7) that transmits an initialization voltage VINT (see FIG. 7), and a reference voltage line VRL (see FIG. 7) that transmits a reference voltage VREF (see FIG. 7).

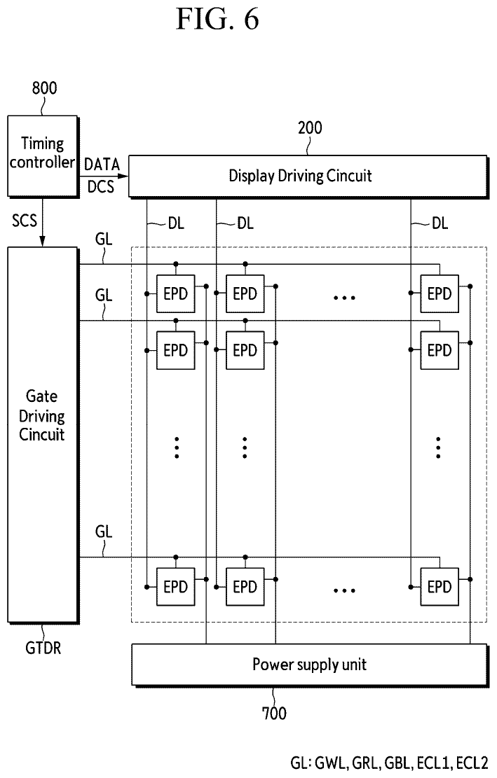

The circuit layer 120 may further include data lines DL (see FIGS. 6 and 7) which transmit data signals Vdata (see FIG. 7) of the pixel circuits EPD (see FIG. 5).

The sealing layer 140 may cover the element layer 130. The sealing layer 140 may include a structure in which two or more inorganic layers and at least one organic layer are alternately stacked.

The touch sensor layer 150 may be located on the sealing layer 140 and may correspond to the main area MA. The touch sensor layer 150 may include touch electrodes for detecting a touch of a person or an object.

The polarizing layer 160 blocks external light reflected from the touch sensor layer 150, the sealing layer 140, the element layer 130, the circuit layer 120 and interfaces between the touch sensor layer 150, the sealing layer 140, the element layer 130 and the circuit layer 120 to prevent a reduction in image visibility due to reflection of the external light.

As a portion of the sub-area SBA is changed into a bent shape, the display driving circuit 200 mounted on the sub-area SBA and the display circuit board 300 connected to a side of the sub-area SBA may be placed under the substrate 110.

The display driving circuit 200 may be electrically connected to the data lines DL (see FIGS. 6 and 7) of the circuit layer 120. The display driving circuit 200 may transmit the data signals Vdata (see FIG. 7) of the pixel circuits EPD (see FIG. 5) through the data lines DL based on control signals and power voltages supplied from the display circuit board 300.

The display driving circuit 200 may be provided as an integrated circuit and may be mounted on the sub-area SBA of the display device 100 using a COG method, a COP method, or an ultrasonic method. However, this is merely an example, and the present disclosure is not limited to this example. For example, the display driving circuit 200 may also be mounted on the display circuit board 300.

An end of the display circuit board 300 may be attached onto pads located at an edge of the sub-area SBA of the display device 100 using an anisotropic conductive film.

The display circuit board 300 may be a flexible printed circuit board (FPCB) that can be bent, a rigid printed circuit board that maintains a flat shape, or a composite printed circuit board including both a rigid printed circuit board and a flexible printed circuit board.

The display circuit board 300 may be connected to signal pads located at a side of the sub-area.

The touch driving circuit 400 may be mounted on the display circuit board 300.

The touch driving circuit 400 may be electrically connected to the touch sensor layer 150 of the display device 100.

The touch driving circuit 400 may apply touch driving signals to driving lines of the touch sensor layer 150 and receive touch sensing signals from sensing lines. In addition, the touch driving circuit 400 may determine whether a user's touch or proximity has occurred by sensing amounts of charge change in capacitances based on the touch sensing signals.

The user's touch indicates that an object, such as the user's finger and/or a pen, directly touches an upper surface of the cover window located on the touch sensor layer. The user's proximity indicates that an object, such as the user's finger and/or a pen, hovers above the upper surface of the cover window.

The touch driving circuit 400 may output touch data including the user's touch coordinates to the main processor 15 (see FIG. 2).

FIG. 5 is a plan view of a portion B of FIG. 3.

As illustrated in FIG. 5, the display area DA may include emission areas EA that emit light and a non-emission area NEA that is an area between the emission areas EA and does not emit light.

Each of the emission areas EA may be a unit area that emits light of a wavelength band corresponding to one of two or more different colors with a luminance corresponding to an image signal.

Each of the emission areas EA may have a quadrangular shape.

However, this is merely an example, and the planar shape of each emission area EA according to one or more embodiments is not limited to the shape illustrated in FIG. 5. That is, the emission areas EA may also have a non-rhombic polygonal shape, such as a rectangle, a square, a hexagon or an octagon, a circular shape, or an oval shape in a plan view.

The emission areas EA may include first emission areas EA1 for emitting light of a first wavelength band, second emission areas EA2 for emitting light of a second wavelength band lower than the first wavelength band, and third emission areas EA3 for emitting light of a third wavelength band lower than the second wavelength band.

For example, the first wavelength band may be about 600 nm to about 750 nm and may correspond to red. The second wavelength band may be about 480 nm to about 560 nm and may correspond to green. The third wavelength band may be about 370 nm to about 460 nm and may correspond to blue.

However, this is merely an example, and the first wavelength band, the second wavelength band, and the third wavelength band according to one or more embodiments are not limited to this example.

Because the emission areas EA include the first emission areas EA1, the second emission areas EA2, and the third emission areas EA3, unit pixels PX may each be formed by a combination of one or more first emission areas EA1, one or more second emission areas EA2, and one or more third emission areas EA3 adjacent to each other among the emission areas EA.

Each of the unit pixels PX may be a unit that displays various colors including white. That is, light of various colors displayed by each unit pixel PX may be realized as a mixture of light emitted from two or more emission areas EA included in each unit pixel PX.

The third emission areas EA3 may have a greater width than the first emission areas EA1, and the first emission areas EA1 may have a greater width than the second emission areas EA2. However, this is merely an example, and the width of each of the emission areas EA is not limited to the width illustrated in FIG. 5.

The first emission areas EA1 and the third emission areas EA3 may be alternately arranged along the first direction DR1.

The second emission areas EA2 may be arranged side by side in the second direction DR2.

Each of the second emission areas EA2 may neighbor a first emission area EA1 or a third emission area EA3 in diagonal directions DR4 and DR5 intersecting the first direction DR1 and the second direction DR2.

In this case, each of the unit pixels PX may include one first emission area EA1 and one third emission area EA3 neighboring each other in the first direction DR1 and two second emission areas EA2 neighboring the first emission area EA1 and the third emission area EA3 in the diagonal directions DR4 and DR5. However, this is merely an example, and the arrangement of the emission areas EA according to one or more embodiments and the elements of each unit pixel PX are not limited to the above description.

According to one or more embodiments, the circuit layer 120 (see FIG. 4) may include pixel circuits EPD arranged in the display area DA along the first direction DR1 and the second direction DR2.

The pixel circuits EPD may be electrically connected to light emitting elements LE (see FIG. 7) of the element layer 130 (see FIG. 4), respectively. The light emitting elements LE may be located in the emission areas EA, respectively.

FIG. 6 is a block diagram of the display device 100 of FIG. 2.

Referring to FIG. 6, the circuit layer 120 of the display device 100 according to one or more embodiments may include pixel circuits EPD electrically connected to the light emitting elements LE (see FIG. 7) located in the emission areas EA of the display area DA and one or more gate lines GL transmitting one or more gate signals to the pixel circuits EPD.

The circuit layer 120 may further include data lines DL that transmit data signals Vdata (see FIG. 7) of the pixel circuits EPD.

According to one or more embodiments, the display device 100 may further include the display driving circuit 200 that outputs the data signals Vdata (see FIG. 7) of the pixel circuits EPD to the data lines DL to control the luminance of each of the light emitting elements LE (see FIG. 7).

According to one or more embodiments, the display device 100 may further include a gate driving circuit GTDR that outputs gate signals to the gate lines GL, a power supply unit 700 that supplies powers and voltages to the pixel circuits EPD, and a timing controller 800 that controls the driving timing of each of the display driving circuit 200 and the gate driving circuit GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driving circuit GTDR.

The display driving circuit 200 may convert the image data DATA into analog data voltages and output the analog data voltages to the data lines DL.

The gate driving circuit GTDR may generate gate signals according to the scan control signal SCS and sequentially output the gate signals to the gate lines GL.

The gate lines GL may include a write scan line GWL that transmits a write scan signal GW (see FIG. 7), a reset control line GRL that transmits a reset control signal GR (see FIG. 7), a bias scan line GBL that transmits a bias scan signal GB (see FIG. 7), a first emission control line ECL1 that transmits a first emission control signal EC1 (see FIG. 7), and a second emission control line ECL2 that transmits a second emission control signal EC2 (see FIG. 7).

Each of the gate signals may have a pulse that changes to a first gate-level voltage or a second gate-level voltage.

The power supply unit 700 may supply various powers and voltages necessary for driving the pixel circuits EPD.

For example, the power supply unit 700 may supply a first driving voltage ELVDD (see FIG. 7) and second power ELVSS (see FIG. 7) for generating a driving signal to be transmitted to the light emitting elements LE, a reference voltage VREF (see FIG. 7) for initializing the pixel circuits EPD, and an initialization voltage VINT (see FIG. 7) for initializing the light emitting elements LE (see FIG. 7).

FIG. 7 is an equivalent circuit diagram of a conventional pixel circuit.

A circuit disclosed in the present specification may include a plurality of transistors. Each of the transistors may be an oxide thin-film transistor (TFT) including an oxide semiconductor or a low-temperature polysilicon (LTPS) TFT including LTPS.

A transistor is a three-electrode switching element including a gate, a source, and a drain. The source is an electrode that supplies carriers to the transistor. In the transistor, the carriers start to flow from the source. The drain is an electrode through which the carriers exit the transistor. In the transistor, the carriers flow from the source to the drain.

In the case of an n-channel transistor, the carriers are electrons. Therefore, a source voltage is lower than a drain voltage so that the electrons can flow from the source to the drain. In the n-channel transistor, a current flows from the drain to the source. In the case of a p-channel transistor, the carriers are holes. Therefore, the source voltage is higher than the drain voltage so that the holes can flow from the source to the drain. In the p-channel transistor, because the holes flow from the source to the drain, a current flows from the source to the drain. It should be noted that the source and drain of the transistor are not fixed. For example, the source and the drain can be changed depending on an applied voltage. Therefore, the present disclosure is not limited by the source and drain of the transistor. In the following description, the source and drain of the transistor will be referred to as a first electrode and a second electrode, respectively.

Pixel circuits EPD may be electrically connected to light emitting elements LE. The pixel circuits EPD may be electrically connected to a first driving voltage line VDL that transmits a first driving voltage ELVDD, and the light emitting elements LE may be electrically connected to a second power line VSL that transmits a second driving voltage ELVSS different from the first driving voltage ELVDD. The second driving voltage ELVSS may have a lower voltage level than the first driving voltage ELVDD.

An anode of a light emitting element LE may be electrically connected to a pixel circuit EPD, and a cathode of the light emitting element LE may be electrically connected to the second power line VSL. The pixel circuit EPD may be electrically connected to a data line DL that transmits a data signal Vdata, a reference voltage line VRL that transmits a reference voltage VREF, and an initialization voltage line VIL that transmits an initialization voltage VINT.

The pixel circuit EPD may be electrically connected to a write scan line GWL that transmits a write scan signal GW, a reset control line GRL that transmits a reset control signal GR, a bias scan line GBL that transmits a bias scan signal GB, a first emission control line ECL1 that transmits a first emission control signal EC1, and a second emission control line ECL2 that transmits a second emission control signal EC2.

The pixel circuit EPD may include a first transistor T1 that generates a driving current of the light emitting element LE, two or more transistors T2 through T6 that are electrically connected to the first transistor T1, and one or more capacitors C1 and C2.

A second transistor T2 may be electrically connected between a gate electrode of the first transistor T1 and the data line DL. The second transistor T2 may be turned on by the write scan signal GW of the write scan line GWL. When the second transistor T2 is turned on, the data signal Vdata of the data line DL may be transmitted to the gate electrode of the first transistor T1.

When a voltage difference between the gate electrode of the first transistor T1 and a first electrode (e.g., a source electrode) of the first transistor T1 becomes equal to or greater than a threshold voltage of the first transistor T1 due to the data signal Vdata applied to the gate electrode of the first transistor T1, the first transistor T1 may be turned on. Accordingly, a drain-source current of the first transistor T1 may be generated with a magnitude corresponding to the data signal Vdata.

A third transistor T3 may be electrically connected between the gate electrode of the first transistor T1 and the reference voltage line VRL. The third transistor T3 may be turned on by the reset control signal GR of the reset control line GRL. When the third transistor T3 is turned on, the potential of the gate electrode of the first transistor T1 may be initialized to the reference voltage VREF of the reference voltage line VRL.

A fourth transistor T4 may be electrically connected between the light emitting element LE and the initialization voltage line VIL. The fourth transistor T4 may be turned on by the bias scan signal GB of the bias scan line GBL. When the fourth transistor T4 is turned on, the potential of the anode of the light emitting element LE may be initialized to the initialization voltage VINT of the initialization voltage line VIL.

A fifth transistor T5 may be electrically connected between a second electrode of the first transistor T1 and the first driving voltage line VDL. The fifth transistor T5 may be turned on by the first emission control signal EC1 of the first emission control line ECL1.

A sixth transistor T6 may be electrically connected between the first electrode of the first transistor T1 and the light emitting element LE. The sixth transistor T6 may be turned on by the second emission control signal EC2 of the second emission control line ECL2.

When the fifth transistor T5 and the sixth transistor T6 are turned on, the first transistor T1 and the light emitting element LE are connected in series between the first driving voltage ELVDD and the second driving voltage ELVSS. Therefore, the drain-source current of the first transistor T1, which is generated with a magnitude corresponding to the data signal Vdata, may be transmitted to the light emitting element LE. Accordingly, the light emitting element LE may emit light with a luminance corresponding to the data signal Vdata.

A first group capacitor C1 may be electrically connected between the gate electrode of the first transistor T1 and the first electrode of the first transistor T1. Accordingly, the first group capacitor C1 may be charged with the data signal Vdata applied to the gate electrode of the first transistor T1, and the first transistor T1 may remain turned on for a selected period of time due to the voltage that charges the first group capacitor C1.

A second group capacitor C2 may be electrically connected between the first electrode of the first transistor T1 and the first driving voltage line VDL. The voltage of the first group capacitor C1 may correspond to a potential difference between the gate electrode of the first transistor T1 and the first electrode of the first transistor T1, may be changed by the data signal Vdata, and may be divided by the second group capacitor C2. Accordingly, the threshold voltage of the first transistor T1 can be compensated.

According to one or more embodiments, the first transistor T1 may include a gate electrode facing a surface of a channel portion and a gate additional electrode facing another surface of the channel portion. The channel portion of the first transistor T1 may be located between the gate electrode and the gate additional electrode.

The gate electrode of the first transistor T1 may be electrically connected to the second transistor T2. A back-gate electrode of the first transistor T1 may be electrically connected to the first electrode of the first transistor T1.

Accordingly, when the first transistor T1 is turned on in response to the data signal Vdata applied to the gate electrode of the first transistor T1, at least a portion of the channel portion of the first transistor T1, which is adjacent to the gate electrode, may be activated, whereas the other portion of the channel portion of the first transistor T1, which is adjacent to the gate additional electrode, is not activated.

Therefore, the electron mobility in the channel portion of the first transistor T1 may be reduced, and the slope of a current curve representing the relationship between the voltage of the gate electrode of the first transistor T1 and the source-drain current may become gentle. Accordingly, the driving voltage range of the first transistor T1 may be widened, thereby improving the ease of luminance control.

According to one or more embodiments, the first transistor T1 may be an n-channel transistor, and at least some of the second through sixth transistors T2 through T6 may be p-channel transistors. For example, the fifth transistor T5 may be a p-channel transistor, and the second transistor T2, the third transistor T3, the fourth transistor T4 and the sixth transistor T6 may be n-channel transistors.

In one or more embodiments, the first transistor T1 may be an oxide TFT including an oxide semiconductor. Compared with an LTPS TFT, an oxide TFT has similar threshold voltages between pixels. Therefore, when the oxide TFT is used as a driving transistor, uniformity related to the threshold voltage characteristics of the driving transistor across the entire screen can be improved.

Because a channel layer of the oxide TFT is manufactured based on an amorphous semiconductor, there may be a difference in threshold voltage between driving transistors when viewed across the entire display panel. However, because there is almost no difference in threshold voltage between pixels within a local area, the uniformity described above can be improved. In the case of the LTPS TFT, the difference in threshold voltage between adjacent driving transistors may increase depending on the location of a grain boundary due to the characteristics of polycrystalline silicon.

In the pixel circuit EPD, if the capacity of the first group capacitor C1 is not secured, the data voltage Vdata corresponding to the color realized by a pixel may not be sufficiently stored. In addition, because the data voltage Vdata is not sufficiently maintained, the state of the pixel cannot change quickly, thus causing afterimages. In some cases, the storage cycle of the data voltage Vdata may need to be shortened, which may increase the power consumption of a display device.

The present specification presents a plan and cross-sectional views, which will be described later, and a modified circuit diagram in which the connection relationship between layers in a plan and cross-sectional views are shown in a circuit diagram together with contact holes. Accordingly, a method of implementing the first group capacitor C1 with sufficient capacity is disclosed.

In order to focus on the description related to securing the capacity of the first group capacitor C1, only some (PEPD) of the elements included in the equivalent circuit diagram of FIG. 7 may be disclosed in the drawings to be described later. For example, the sixth transistor T6, the fourth transistor T4, etc. disclosed in the equivalent circuit diagram may not be shown in the drawings to be described later.

The plan views, cross-sectional views, etc. disclosed in the present specification may include a plurality of layers or films. At least some of the layers may be elements included in the circuit layer 120 described above, and the rest may be elements included in the element layer 130 described above.

For example, the circuit layer 120 described above may include a bottom metal layer, a first semiconductor layer, a first gate metal layer, a second gate metal layer, a second semiconductor layer, a third gate metal layer, a first connection metal layer, a second connection metal layer, etc. In addition, the circuit layer 120 described above may include a buffer layer, a first gate insulating layer, a second gate insulating layer, a first interlayer insulating film, a third gate insulating layer, a second interlayer insulating film, a first planarization layer, a second planarization layer, etc.

The element layer 130 described above may include an anode, a light emitting layer, a cathode, a bank, etc.

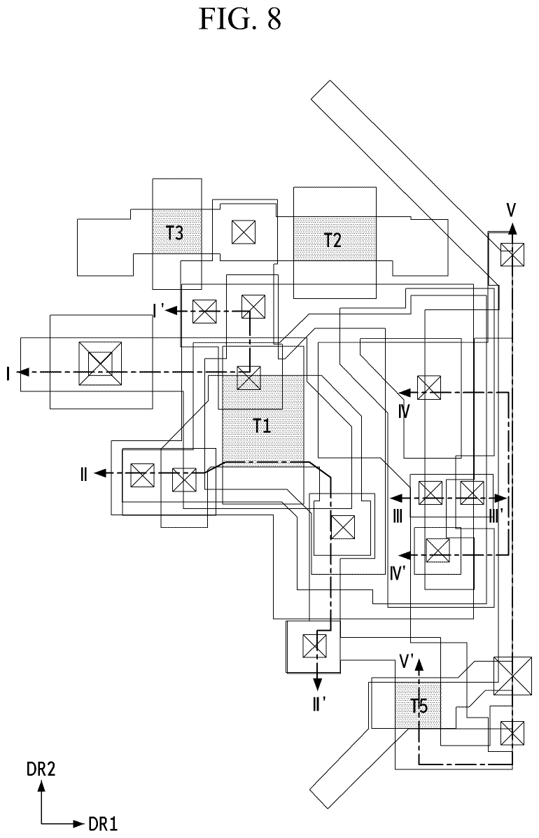

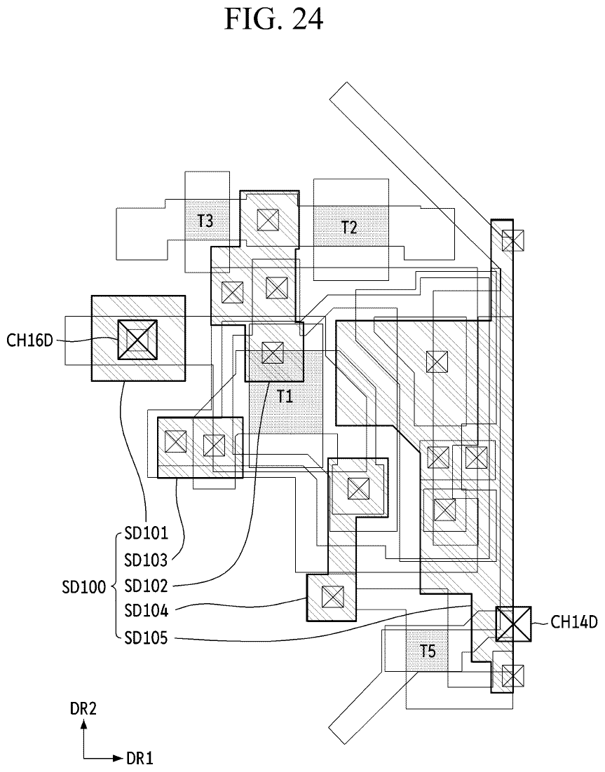

FIGS. 8, 11, 13, 15, 17, 19, 21, 23, and 24 are plan views illustrating a plurality of layers included in a subpixel according to one or more embodiments of the present specification.

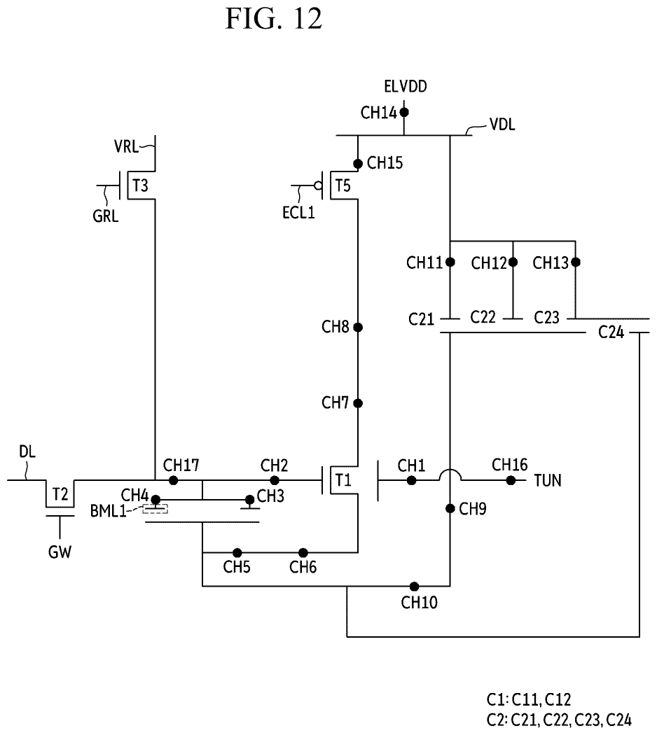

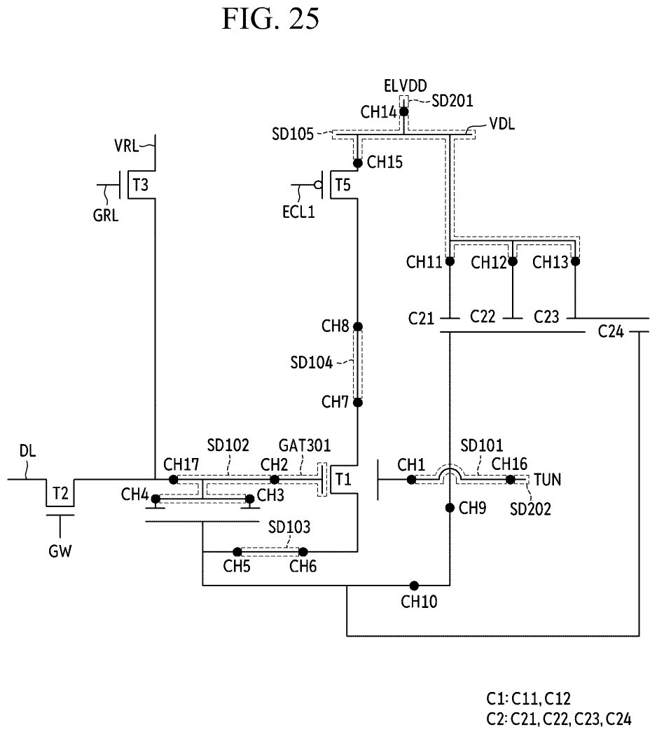

FIGS. 12, 14, 16, 18, 20, 22, and 25 are modified circuit diagrams illustrating the layers and contact holes related to the layers in the subpixel according to one or more embodiments of the present disclosure.

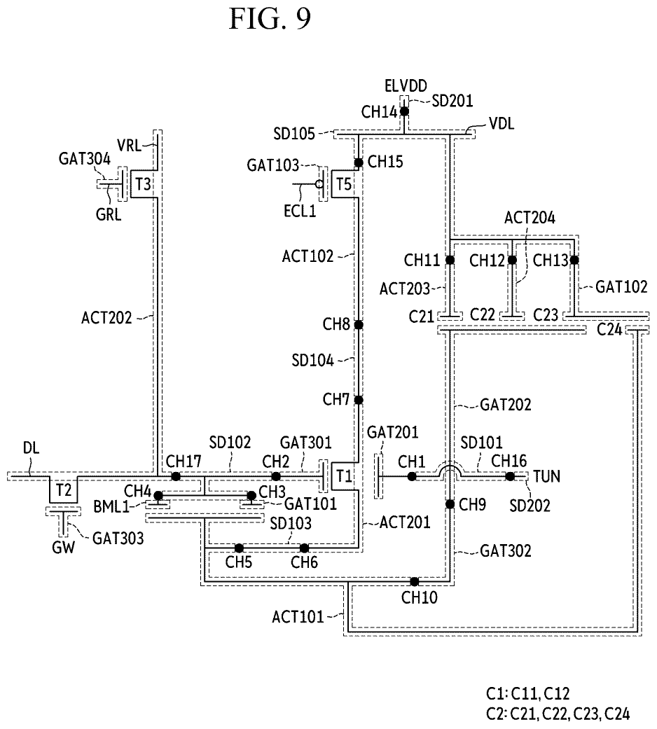

FIG. 9 is a modified circuit diagram illustrating the connection relationship between a plurality of layers in a circuit layer included in the subpixel according to one or more embodiments of the present disclosure, together with a plurality of contact holes.

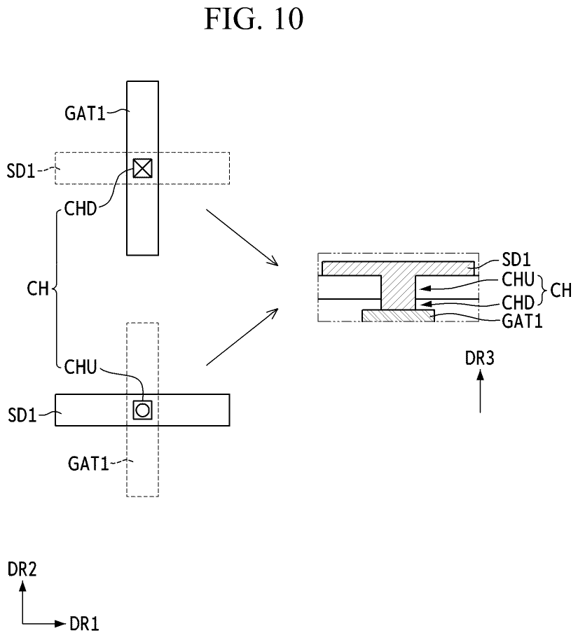

FIG. 10 illustrates a notation method for explaining the connection relationship between a plurality of layers and a contact hole disclosed in the present disclosure.

FIG. 8 is a plan view of the circuit layer included in the subpixel according to one or more embodiments of the present disclosure.

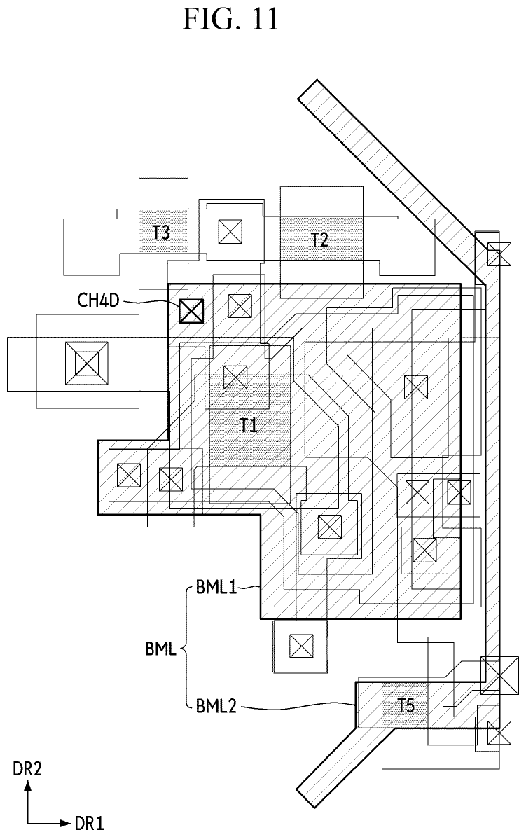

FIGS. 11 and 12 are a plan view and a modified circuit diagram illustrating a bottom metal layer and contact holes related to the bottom metal layer in the subpixel according to one or more embodiments of the present specification.

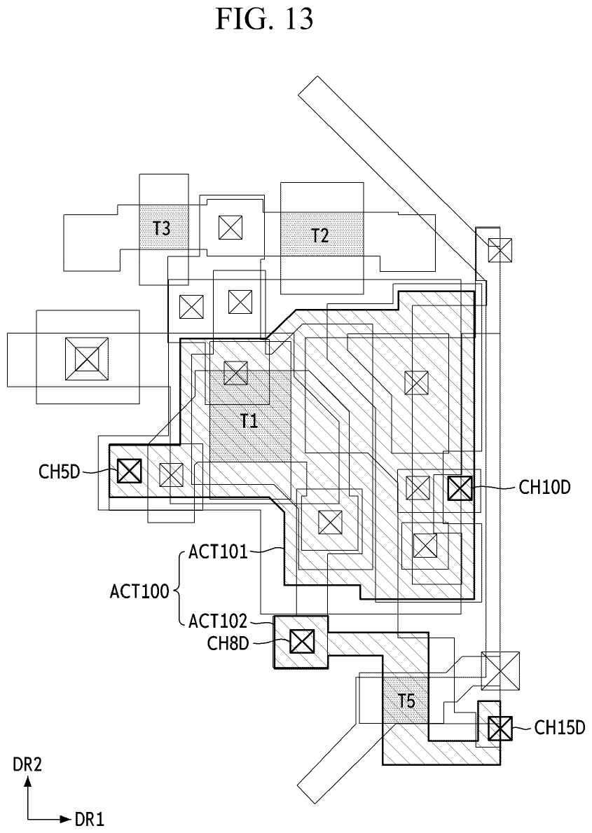

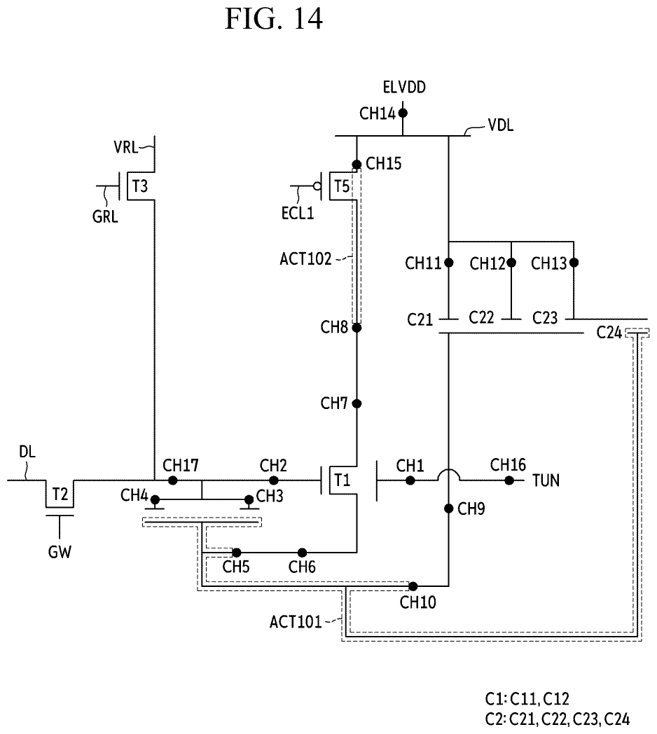

FIGS. 13 and 14 are a plan view and a modified circuit diagram illustrating a first semiconductor layer and contact holes related to the first semiconductor layer in the subpixel according to one or more embodiments of the present disclosure.

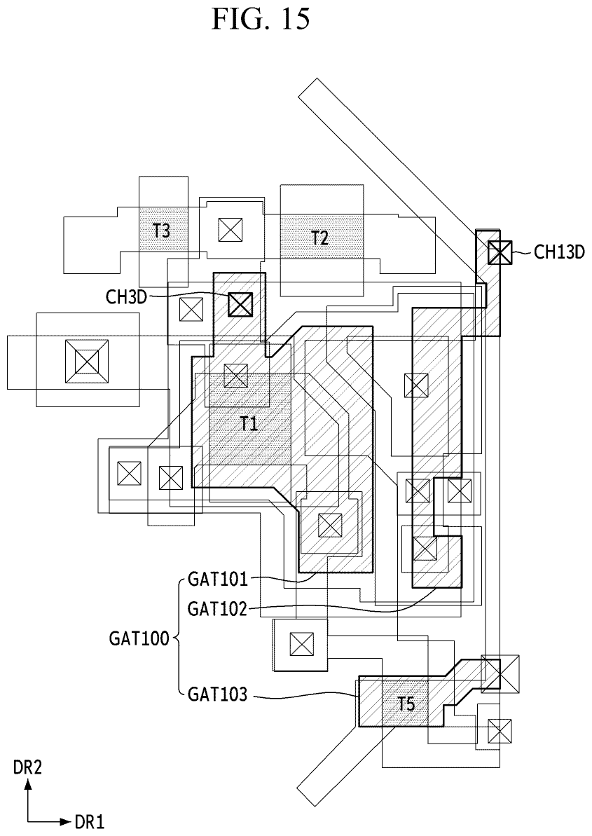

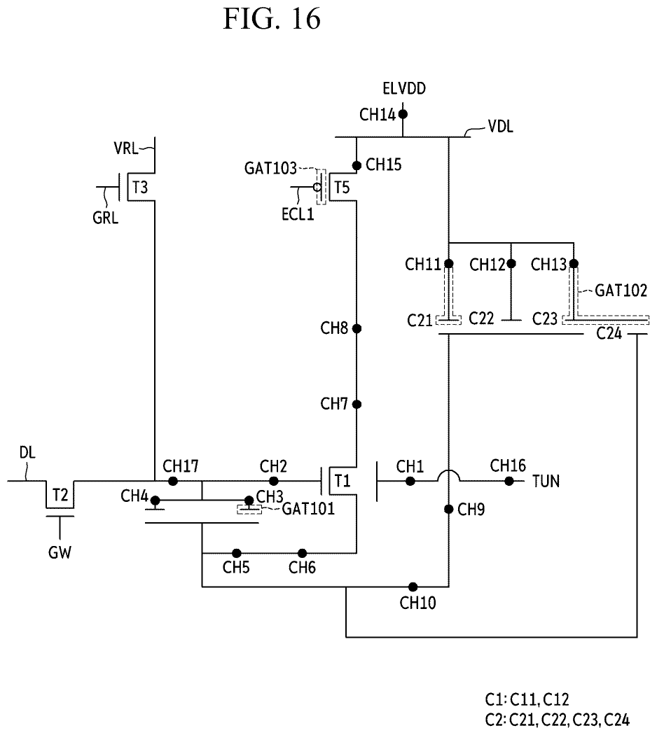

FIGS. 15 and 16 are a plan view and a modified circuit diagram illustrating a first gate metal layer and contact holes related to the first gate metal layer in the subpixel according to one or more embodiments of the present disclosure.

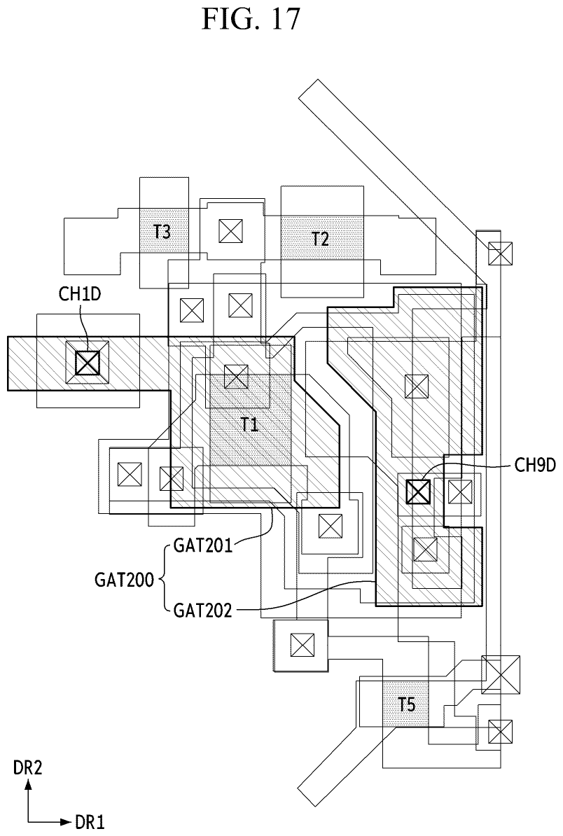

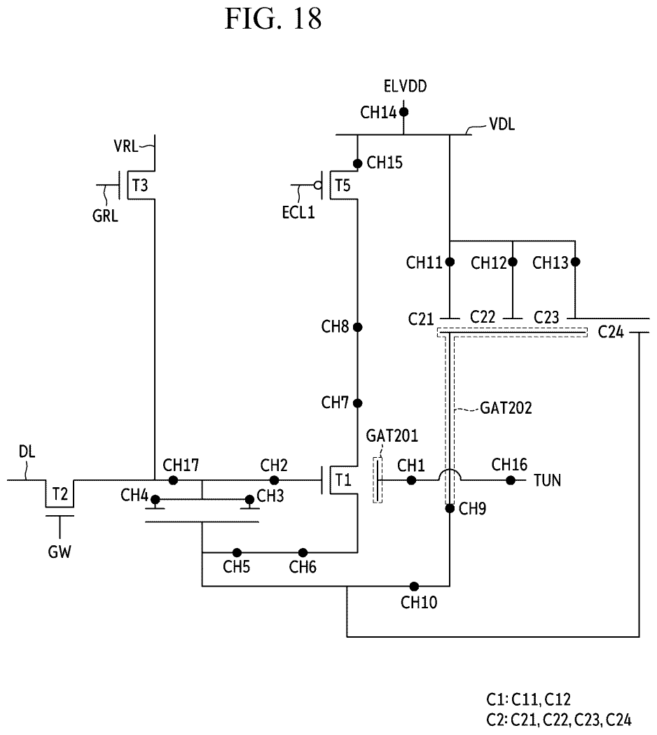

FIGS. 17 and 18 are a plan view and a modified circuit diagram illustrating a second gate metal layer and contact holes related to the second gate metal layer in the subpixel according to one or more embodiments of the present disclosure.

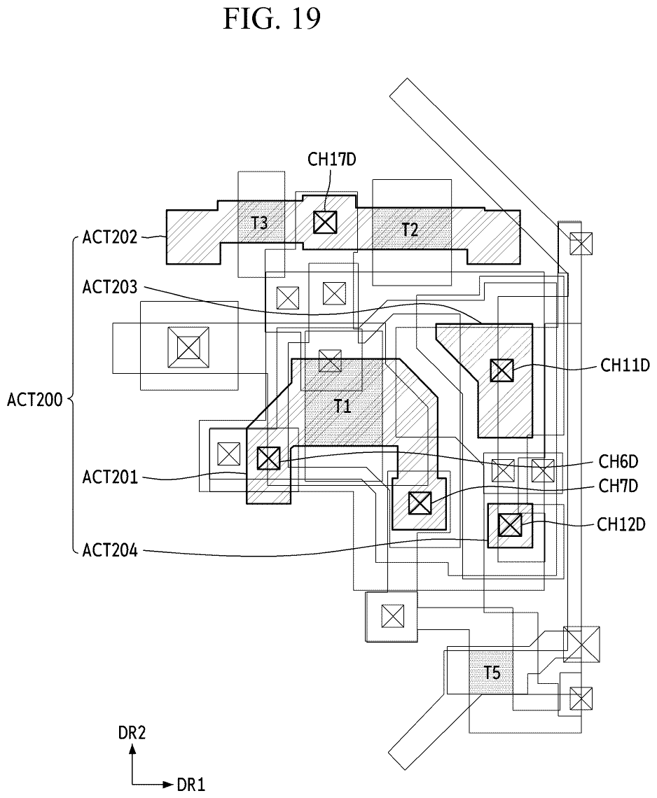

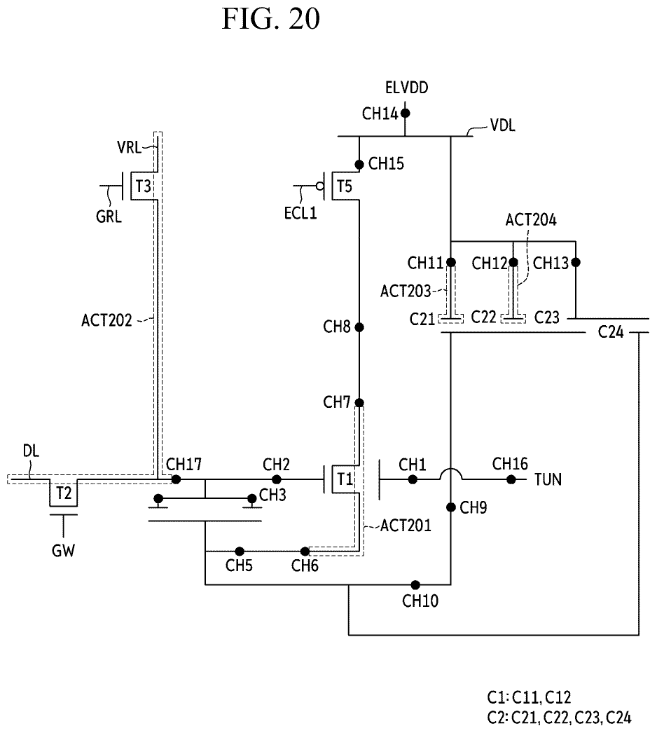

FIGS. 19 and 20 are a plan view and a modified circuit diagram illustrating a second semiconductor layer and contact holes related to the second semiconductor layer in the subpixel according to one or more embodiments of the present disclosure.

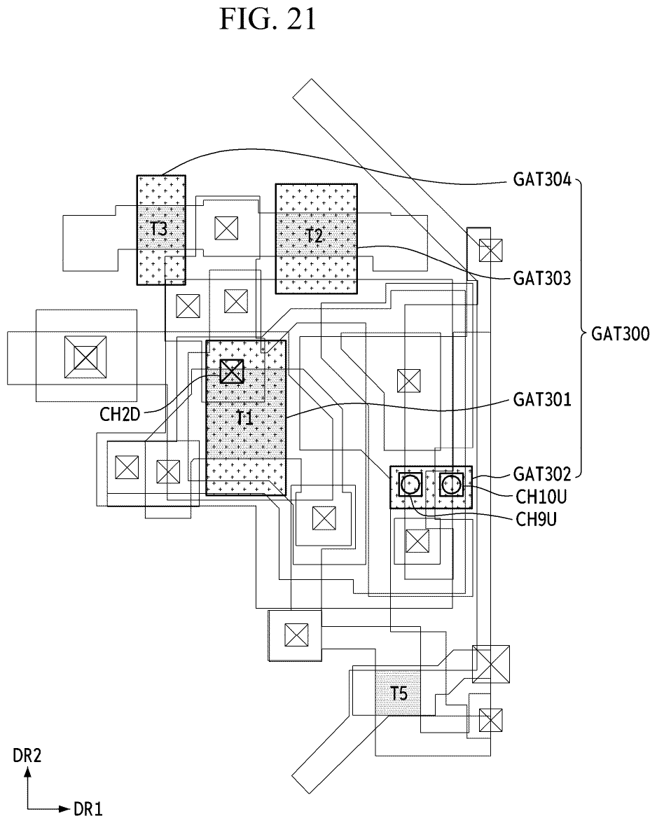

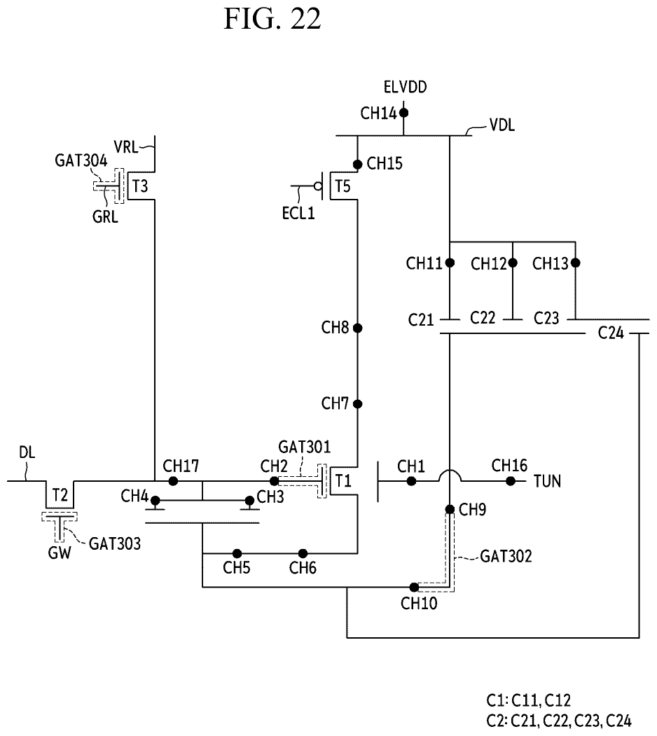

FIGS. 21 and 22 are a plan view and a modified circuit diagram illustrating a third gate metal layer and contact holes related to the third gate metal layer in the subpixel according to one or more embodiments of the present specification.

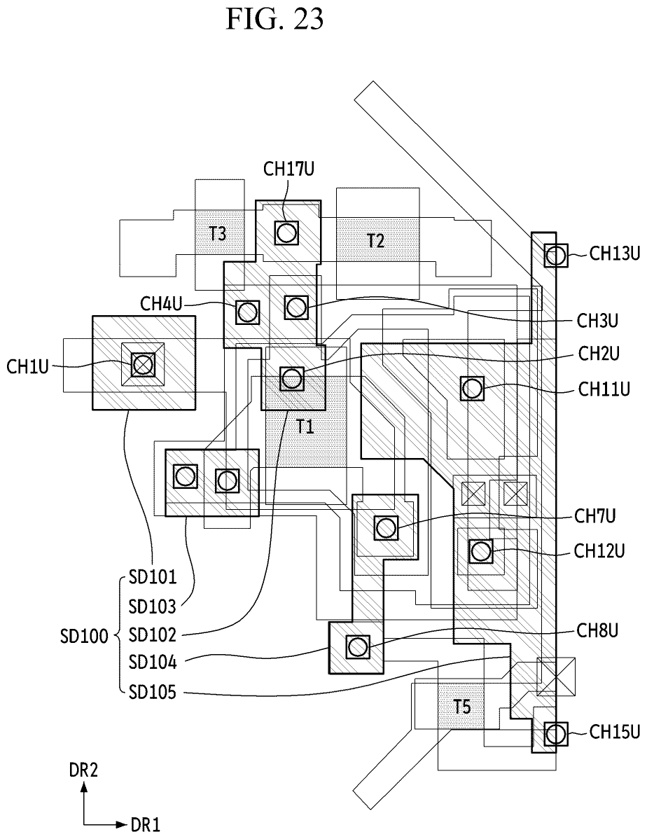

FIGS. 23, 24, and 25 are plan views and a modified circuit diagram illustrating a first connection metal layer and contact holes related to the first connection metal layer in the subpixel according to the embodiment of the present specification.

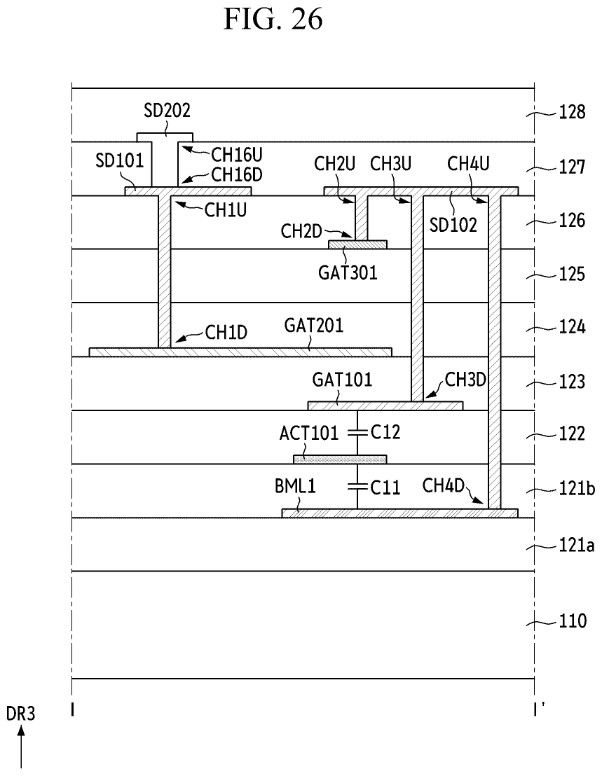

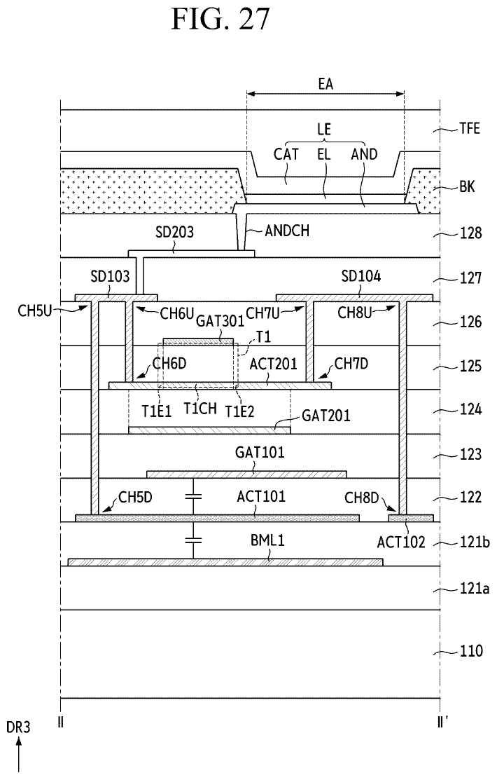

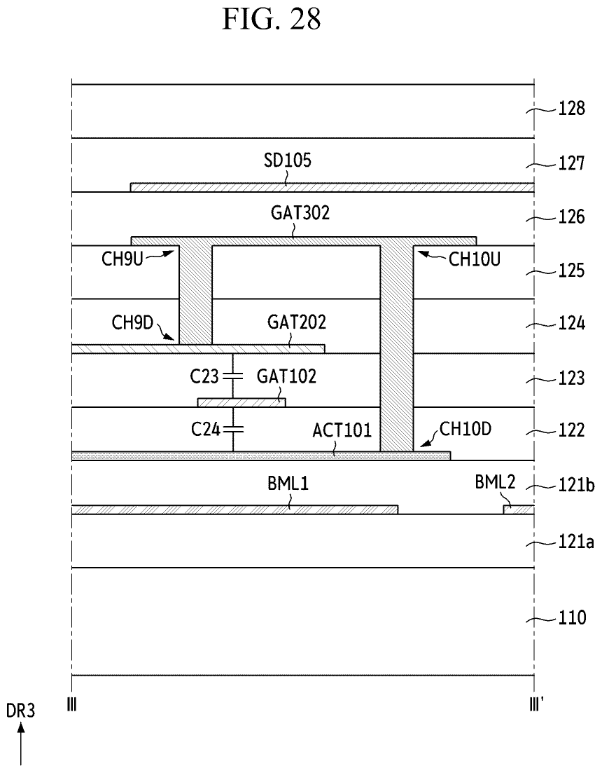

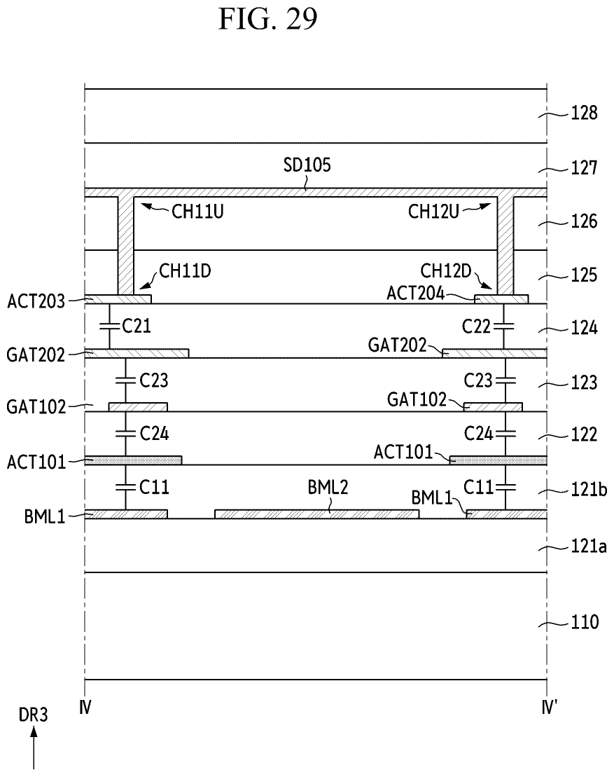

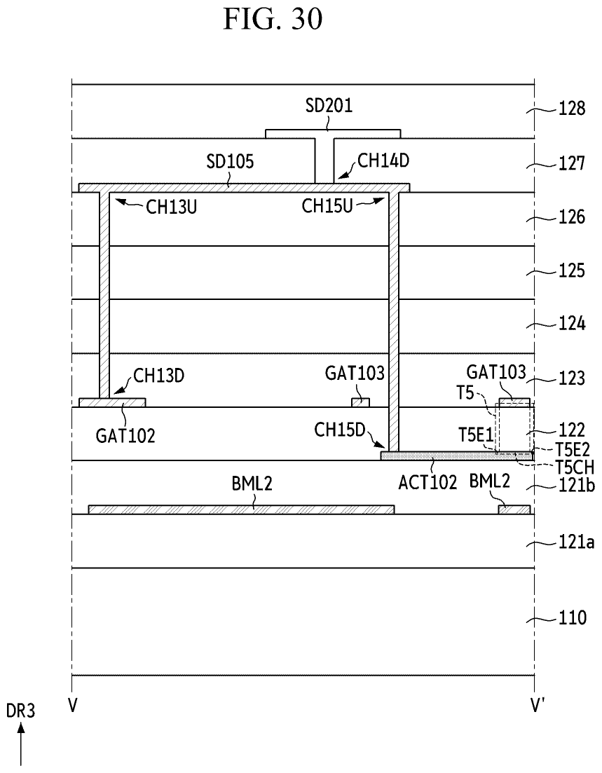

FIG. 26 is a cross-sectional view taken along the line I-I′ of FIG. 8. FIG. 27 is a cross-sectional view taken along the line II-II′ of FIG. 8. FIG. 28 is a cross-sectional view taken along the line III-III′ of FIG. 8. FIG. 29 is a cross-sectional view taken along the line IV-IV′ of FIG. 8. FIG. 30 is a cross-sectional view taken along the line V-V′ of FIG. 8.

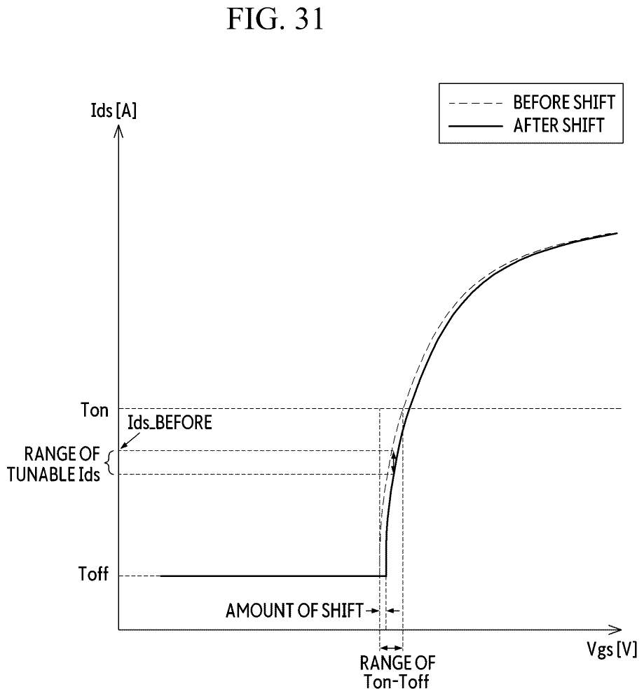

FIG. 31 is a graph illustrating the change in driving current according to the application of a back-gate voltage to a first transistor.

Although a number of drawings are disclosed, they merely illustrate a bottom metal layer BML, a first semiconductor layer ACT100, a first gate metal layer GAT100, a second gate metal layer GAT200, a second semiconductor layer ACT200, a third gate metal layer GAT300, and a first connection metal layer SD100, respectively.

A plurality of subpixels may include two subpixels. The two subpixels may be formed symmetrically with respect to a bottom metal layer BML2 of a fifth transistor T5.

Referring to FIG. 11, the bottom metal layer BML may include a first electrode BML1 of a first capacitor C11 and a fifth bottom metal layer BML2. The first electrode BML1 of the first capacitor C11 may be formed in multiple numbers, one for each subpixel. The fifth bottom metal layer BML2 may be formed as a layer common to two subpixels.

Referring to FIG. 13, the first semiconductor layer ACT100 may include a second electrode ACT101 of the first capacitor C11 and an active layer ACT102 of the fifth transistor T5. The second electrode ACT101 of the first capacitor C11 may be formed in multiple numbers, one for each subpixel. The active layer ACT102 of the fifth transistor T5 may be formed as a layer common to two subpixels.

Referring to FIG. 15, the first gate metal layer GAT100 may include a first electrode GAT101 of a second capacitor C12, a first electrode GAT102 of a fifth capacitor C23, and a gate electrode GAT103 of the fifth transistor T5. The first electrode GAT101 of the second capacitor C12 may be formed in multiple numbers, one for each subpixel. The first electrode GAT102 of the fifth capacitor C23 and the gate electrode GAT103 of the fifth transistor T5 may each be formed as a layer common to two subpixels.

Referring to FIG. 17, the second gate metal layer GAT200 may include a bottom gate electrode GAT201 of a first transistor T1 and a second electrode GAT202 of a third capacitor C21. The bottom gate electrode GAT201 of the first transistor T1 and the second electrode GAT202 of the third capacitor C21 may be formed in multiple numbers, one for each subpixel.

Referring to FIG. 19, the second semiconductor layer ACT200 may include an active layer ACT201 of the first transistor T1, an active layer ACT202 of a second transistor T2 (or an active layer of a third transistor T3), a first electrode ACT203 of the third capacitor C21, and a first electrode ACT204 of a fourth capacitor C22. These elements may be formed in multiple numbers, one for each subpixel.

Referring to FIG. 21, the third gate metal layer GAT300 may include a gate electrode GAT301 of the first transistor T1, a first connection electrode GAT302, a gate electrode GAT303 of the second transistor T2, and a gate electrode GAT304 of the third transistor T3. These elements may be formed in multiple numbers, one for each subpixel.

Referring to FIG. 23, the first connection metal layer SD100 may include a second connection electrode SD101, a third connection electrode SD102, a first anode connection electrode SD103, a fifth connection electrode SD104, and a sixth connection electrode SD105. The second connection electrode SD101, the third connection electrode SD102, the first anode connection electrode SD103, and the fifth connection electrode SD104 may be formed in multiple numbers, one for each subpixel. The sixth connection electrode SD105 may be formed as a layer common to two subpixels.

Referring to FIG. 10, different symbols indicating a lower portion CHD of a contact hole CH and an upper portion CHU of the contact hole CH are shown in plan views. The contact hole CH may include the lower portion CHD of the contact hole CH and the upper portion CHU of the contact hole CH. A cross-sectional view may be produced by combining the plan view including the lower portion CHD of the contact hole CH with the plan view including the upper portion CHU of the contact hole CH.

For example, the lower portion CHD of the contact hole CH and the upper portion CHU of the contact hole CH may be formed in an area where a first connection metal layer SD1 and a first gate metal layer GAT1 overlap. When these are combined, they may be expressed as shown in the cross-sectional view. Here, the contact hole CH may be formed in at least one layer located between the first gate metal layer GAT1 and the first connection metal layer SD1. The first connection metal layer SD1 may be formed from the upper portion CHU of the contact hole CH to the lower portion CHD of the contact hole CH. The first connection metal layer SD1 may contact the first gate metal layer GAT1 in the lower portion CHD of the contact hole CH. When each of the first connection metal layer SD1 and the first gate metal layer GAT1 has conductivity, the first connection metal layer SD1 and the first gate metal layer GAT1 may be electrically connected to each other by the contact hole CH.

Being electrically connected is a concept that includes not only a case where the first connection metal layer SD1 and the first gate metal layer GAT1 are directly in contact and connected as illustrated in the drawing, but also a case where the first connection metal layer SD1 is directly in contact and electrically connected with another metal layer and the another metal layer is directly in contact and electrically connected with the first gate metal layer GAT1 so that the first connection metal layer SD1 and the first gate metal layer GAT1 can be indirectly in contact and connected.

Referring to FIGS. 8, 26, and 27, a first buffer layer 121a may be formed on a substrate 110 of a display device according to one or more embodiments, and the bottom metal layer BML including the first electrode BML1 of the first capacitor C11 may be formed on the first buffer layer 121a.

The first semiconductor layer ACT100 including the second electrode ACT101 of the first capacitor C11 and the active layer ACT102 of the fifth transistor T5 may be formed on a second buffer layer 121b covering the first electrode BML1 of the first capacitor C11.

The first gate metal layer GAT100 including the first electrode GAT101 of the second capacitor C12 may be formed on a first gate insulating layer 122 covering the second electrode ACT101 of the first capacitor C11 and the active layer ACT102 of the fifth transistor T5.

The second gate metal layer GAT200 including the bottom gate electrode GAT201 of the first transistor T1 may be formed on a second gate insulating layer 123 covering the first electrode GAT101 of the second capacitor C12.

The second semiconductor layer ACT200 including the active layer ACT201 of the first transistor T1 may be formed on a first interlayer insulating film 124 covering the bottom gate electrode GAT201 of the first transistor T1.

The third gate metal layer GAT300 including the gate electrode GAT301 of the first transistor T1 may be formed on a third gate insulating layer 125 covering the active layer ACT201 of the first transistor T1.

The first connection metal layer SD100 including the second connection electrode SD101, the third connection electrode SD102, the first anode connection electrode SD103, the fifth connection electrode SD104, etc. may be formed on a second interlayer insulating film 126 covering the gate electrode GAT301 of the first transistor T1.

A second connection metal layer SD200 including an eighth connection electrode SD202, a second anode connection electrode SD203, etc. may be formed on a first planarization layer 127 covering the second connection electrode SD101, the third connection electrode SD102, the first anode connection electrode SD103, the fifth connection electrode SD104, etc.

The element layer 130 described above may be formed on a second planarization layer 128 covering the eighth connection electrode SD202, the second anode connection electrode SD203, etc. The element layer 130 may include a light emitting element LE and a bank BK.

The light emitting element LE may include an anode AND, a light emitting layer EL, and a cathode CAT. The bank BK may cover at least a portion of an end portion and/or the other end portion of the anode AND and may define an emission area EA.

The substrate 110 may include an insulating material such as polymer resin and/or glass. The substrate 110 may include a glass material. The substrate 110 may include polyimide. In this case, the substrate 110 may be a flexible substrate 110 that can be bent, folded, and/or rolled.

The first buffer layer 121a located on the substrate 110 may include a silicon nitride layer, a silicon oxynitride layer, a silicon oxide layer, a titanium oxide layer, and/or an aluminum oxide layer.

The bottom metal layer BML located on the first buffer layer 121a may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second buffer layer 121b covering the bottom metal layer BML may include a silicon nitride layer, a silicon oxynitride layer, a silicon oxide layer, a titanium oxide layer, and/or an aluminum oxide layer. The second buffer layer 121b may include an inorganic layer that can prevent penetration of air or moisture. The second buffer layer 121b may include a plurality of inorganic layers stacked alternately.

The first semiconductor layer ACT100 located on the second buffer layer 121b may include a silicon semiconductor such as polycrystalline silicon, monocrystalline silicon, low-temperature polycrystalline silicon, and/or amorphous silicon. An electrode may be formed when the first semiconductor layer ACT100 is doped with ions or impurities. The doped first semiconductor layer ACT100 may have conductivity.

The gate insulating layer 122 covering the first semiconductor layer ACT100 may include an inorganic layer, for example, a silicon nitride layer, a silicon oxynitride layer, a silicon oxide layer, a titanium oxide layer, and/or an aluminum oxide layer.

The first gate metal layer GAT100 located on the first gate insulating layer 122 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second gate insulating layer 123 covering the first gate metal layer GAT100 may include an inorganic layer, for example, a silicon nitride layer, a silicon oxynitride layer, a silicon oxide layer, a titanium oxide layer, and/or an aluminum oxide layer.

The second gate metal layer GAT200 located on the second gate insulating layer 123 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The first interlayer insulating film 124 covering the second gate metal layer GAT200 may include an inorganic layer, for example, a silicon nitride layer, a silicon oxynitride layer, a silicon oxide layer, a titanium oxide layer, and/or an aluminum oxide layer.

The second semiconductor layer ACT200 located on the first interlayer insulating film 124 may include an oxide semiconductor. An electrode may be formed when the second semiconductor layer ACT200 is doped with ions or impurities. The doped second semiconductor layer ACT200 may have conductivity.

In one or more embodiments, the first semiconductor layer ACT100 may include a polycrystalline silicon semiconductor material, and the second semiconductor layer ACT200 may include an oxide semiconductor material. Therefore, at least some of the transistors of a pixel circuit may be implemented as oxide TFTs, and at least some other transistors may be implemented as LTPS TFTs. The combined use of oxide TFTs and LTPS TFTs can ensure efficiency in terms of manufacturing cost of a display device while securing electron mobility, etc. Accordingly, a display device with improved color gamut, power consumption, etc. can be provided.

The third gate insulating layer 125 covering the second semiconductor layer ACT200 may include an inorganic layer, for example, a silicon nitride layer, a silicon oxynitride layer, a silicon oxide layer, a titanium oxide layer, and/or an aluminum oxide layer.

The third gate metal layer GAT300 located on the third gate insulating layer 125 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second interlayer insulating film 126 covering the third gate metal layer GAT300 may include an inorganic layer, for example, a silicon nitride layer, a silicon oxynitride layer, a silicon oxide layer, a titanium oxide layer, and/or an aluminum oxide layer.

The first connection metal layer SD100 located on the second interlayer insulating film 126 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The first planarization layer 127 covering the first connection metal layer SD100 may include an organic layer such as acryl resin, epoxy resin, phenolic resin, polyamide resin, and/or polyimide resin.

The second connection metal layer SD200 located on the first planarization layer 127 may be a single layer or a multilayer including one or more of molybdenum (Mo), aluminum (Al), chromium (Cr), gold (Au), titanium (Ti), nickel (Ni), neodymium (Nd), copper (Cu), and/or alloys thereof.

The second planarization layer 128 covering the second connection metal layer SD200 may include an organic layer such as acryl resin, epoxy resin, phenolic resin, polyamide resin, and/or polyimide resin.

The light emitting element LE including the anode AND, the light emitting layer EL, and the cathode CAT may be located on the second planarization layer 128. The anode AND may be electrically connected to the second anode connection electrode SD203 through an anode contact hole ANDCH formed in the second planarization layer 128. In one or more embodiments, the first anode connection electrode SD103 and the second anode connection electrode SD203 may be configured as one anode connection electrode. In this case, the first planarization layer 127 and the second planarization layer 128 may also be configured as one planarization layer.

In a top emission structure in which light is emitted from the light emitting layer EL toward the cathode CAT, the anode AND may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank BK may be formed on the second planarization layer 128 to delimit the anode AND in order to define the emission area EA. The emission area EA is an area in which the anode AND, the light emitting layer EL, and the cathode CAT are sequentially stacked so that holes from the anode AND and electrons from the cathode CAT are combined with each other in the light emitting layer EL to emit light. The bank BK may cover edges of the anode AND. The bank BK may include an organic layer such as acryl resin, epoxy resin, phenolic resin, polyamide resin, and/or polyimide resin.

The light emitting layer EL may be formed on the anode AND. The light emitting layer EL may include an organic material to emit light of a selected color. For example, the light emitting layer EL may include a hole transporting layer, an organic material layer, and an electron transporting layer.

The cathode CAT may be formed on the light emitting layer EL. The cathode CAT may be formed to cover the light emitting layer EL. The cathode CAT may be a common layer formed in common in all emission areas EA including the illustrated emission area EA. A capping layer may be formed on the cathode CAT.

In the top emission structure, the cathode CAT may include a transparent conductive oxide (TCO) that can transmit light, such as indium tin oxide (ITO) or indium zinc oxide (IZO), or a semi-transmissive conductive material such as magnesium (Mg), silver (Ag) or an alloy of Mg and Ag. When the cathode CAT includes a semi-transmissive conductive material, light output efficiency may be increased by a microcavity.

An encapsulating layer TFE may be located on the cathode CAT. The encapsulating layer TFE may include at least one inorganic layer to prevent oxygen and/or moisture from permeating into the light emitting element LE. In addition, the encapsulation layer TFE may include at least one organic layer to protect the light emitting element LE from foreign substances such as dust. For example, the encapsulation layer TFE may include a plurality of inorganic layers and a single organic layer, but the present specification is not limited to this example. The inorganic layer may be a multilayer in which one or more inorganic layers selected from a silicon nitride layer, a silicon oxynitride layer, a silicon oxide layer, a titanium oxide layer, and/or an aluminum oxide layer are alternately stacked. The organic layer may include acryl resin, epoxy resin, phenolic resin, polyamide resin, and/or polyimide resin.

A filling layer, a sealant, and an encapsulation substrate may replace the encapsulation layer TFE. In this case, the encapsulation substrate 110 may be an insulating substrate 110 including an insulating material such as glass and/or plastic. The filling layer may be, but is not limited to, an air layer in a vacuum state. The sealant may be located in a non-display area of a display panel to be around (e.g., to surround) a display area.

Referring to FIG. 9, the modified circuit diagram may include the first transistor T1, the second transistor T2, the third transistor T3, the fifth transistor T5, a first group capacitor C1, and a second group capacitor C2.

The first group capacitor C1 may include the first capacitor C11 and the second capacitor C12. The second group capacitor C2 may include the third capacitor C21, the fourth capacitor C22, the fifth capacitor C23, and a sixth capacitor C24. As described above, when the capacity of the first group capacitor C1 is not sufficiently secured, there may be problems such as deterioration of image quality of a display device and increased power consumption. Therefore, an embodiment disclosed in the present specification may provide a display device that can increase the capacity of the first group capacitor C1.

Referring to the conventional pixel circuit, a first electrode node voltage of the first transistor T1 is applied as a second gate voltage (or a back-gate voltage) to the first transistor T1 (see FIG. 7). The display device according to one or more embodiments of the present specification may apply a third driving voltage TUN as the second gate voltage. The third driving voltage TUN applied as the second gate voltage to the first transistor T1 may shift a driving current curve of the first transistor T1.

Referring to FIG. 31, the driving current curve of the first transistor T1 may change from a pre-shift curve to a post-shift curve as the second gate voltage is applied. Referring to the pre-shift curve, a driving current may change relatively greatly even with a relatively small change in Vgs within a range between a Vgs value for turning off the first transistor T1 and a Vgs value for turning on the first transistor T1. If the curve can be shifted to the left or right by freely adjusting the second gate voltage, the driving current desired by an implementer can be finely adjusted despite a large change in the driving current.

The amount of current supplied to the light emitting element LE is controlled using the amount of driving current flowing through the first transistor T1 as a variable, and consequently, the gray value expression of the light emitting element LE is controlled. In the pre-shift curve, a driving current value Ids_BEFORE corresponding to an arbitrary Vgs value is specified. If the curve is not shifted, the driving current value Ids_BEFORE changes relatively greatly even with a small change in Vgs. If the implementer can shift the driving current curve by a desired amount AMOUNT OF SHIFT by applying the second gate voltage, the curve can move freely after the shift. Accordingly, not the specified driving current value Ids_BEFORE, but a driving current value RANGE OF TUNABLE Ids that can be adjusted within a desired range can be derived.

In the display device according to one or more embodiments of the present specification, the driving current curve can be shifted by freely applying the second gate voltage. In addition, because the shifted driving current curve is utilized, the accuracy of expression of a gray value desired by the implementer can be improved. Accordingly, the color gamut of the display device can be improved.

In the conventional pixel circuit, the second gate voltage is relatively un-adjustable. However, the display device according to one or more embodiments of the present specification can apply a relatively adjustable third driving voltage TUN as the second gate voltage.

Referring again to FIG. 9, the third driving voltage TUN may be applied as the second gate voltage to the first transistor T1. To this end, the bottom gate electrode GAT201 of the first transistor T1, which was previously connected to a first electrode node of the first transistor T1, needs to be separated from the first electrode node of the first transistor T1. Because the second electrode GAT202 of the third capacitor C21, which is connected to the first electrode node of the first transistor T1, forms a second electrode of the second group capacitor C2, the bottom gate electrode GAT201 of the first transistor T1 and the second electrode GAT202 of the third capacitor C21, which were originally connected as one, need to be separated from each other.

One or more embodiments of the present disclosure may solve the problem of insufficient capacity of the first group capacitor C1 due to the bottom gate electrode GAT201 of the first transistor T1 and the second electrode GAT202 of the third capacitor C21 which need to be separated to apply the third driving voltage TUN as the second gate voltage.

In the conventional art, the second gate metal layer GAT200 including the bottom gate electrode GAT201 of the first transistor T1 and the second electrode GAT202 of the third capacitor C21 forms the first group capacitor C1 with the first electrode GAT101 of the second capacitor C12. Specifically, in the conventional art, the second gate metal layer GAT200 (connected to the first electrode node of the first transistor T1) including the bottom gate electrode GAT201 of the first transistor T1 and the second electrode GAT202 of the third capacitor C21 forms a separate capacitor with the first electrode GAT101 of the second capacitor C12 (connected to a gate electrode node of the first transistor T1), in addition to the second capacitor C12 including the second electrode ACT101 of the first capacitor C11 (connected to the first electrode node of the first transistor T1) and the first electrode GAT101 of the second capacitor C12 (connected to the gate electrode node of the first transistor T1). Therefore, all of them (the second capacitor C12 including the second electrode ACT101 of the first capacitor C11 and the first electrode GAT101 of the second capacitor C12 and the separate capacitor including the second gate metal layer GAT200, which includes the bottom gate electrode GAT201 of the first transistor T1 and the second electrode GAT202 of the third capacitor C21, and the first electrode GAT101 of the second capacitor C12) form the first group capacitor C1.

However, when the bottom gate electrode GAT201 of the first transistor T1 and the second electrode GAT202 of the third capacitor C21 are separated as in the embodiment of the present specification, the bottom gate electrode GAT201 of the first transistor T1 overlapping the first electrode GAT101 of the second capacitor C12 does not form the separate capacitor.

Therefore, in order to solve the problem of insufficient capacity of the first group capacitor C1 due to the absence of the separate capacitor, one or more embodiments additionally places the first electrode BML1 of the first capacitor C11 and connects the gate electrode GAT301 of the first transistor T1 to the first electrode BML1 of the first capacitor C11. Accordingly, the first electrode BML1 of the first capacitor C11 is connected to the gate electrode node of the first transistor T1. The additionally formed first electrode BML1 of the first capacitor C11 may form the first capacitor C11 with the second electrode ACT101 of the first capacitor C11 which is also connected to the first electrode node of the first transistor T1 in the conventional art.

The illustrated modified circuit diagram does not show the hierarchical relationship between a plurality of layers. However, the modified circuit diagram shows that the bottom gate electrode GAT201 of the first transistor T1 and the second electrode GAT202 of the third capacitor C21 are separated to apply the third driving voltage TUN and that the first capacitor C11 is formed by the first electrode BML1 of the first capacitor C11 and the second electrode ACT101 of the first capacitor C11. Embodiments of the present specification can solve the problem of insufficient capacity of the first group capacitor C1 due to the bottom gate electrode GAT201 of the first transistor T1 and the second electrode GAT202 of the third capacitor C21 separated to apply the third driving voltage TUN and can improve the performance of the display device.

In one or more embodiments, a pixel circuit of a subpixel may include the first transistor T1 formed by electrically connecting a plurality of layers using a plurality of contact holes or overlapping the layers, the first group capacitor C1 formed between the first electrode node of the first transistor T1 and the gate electrode node of the first transistor T1, and the second group capacitor C2 formed between the first electrode node of the first transistor T1 and a first driving voltage node. The pixel circuit may further include the second transistor T2, the third transistor T3, and the fifth transistor T5.

Referring to FIGS. 9 and 11 through 25, the first transistor T1 may include the active layer ACT201 of the first transistor T1 and the gate electrode GAT301 of the first transistor T1.

The active layer ACT201 of the first transistor T1 may include a first electrode T1E1 of the first transistor T1, a second electrode T1E2 of the first transistor T1, and a first channel portion T1CH formed between the first electrode T1E1 and the second electrode T1E2.

The fifth transistor T5 may include the active layer ACT102 of the fifth transistor T5 and the gate electrode GAT103 of the fifth transistor T5.

The active layer ACT102 of the fifth transistor T5 may include a first electrode T5E1 of the fifth transistor T5, a second electrode T5E2 of the fifth transistor T5, and a fifth channel portion T5CH formed between the first electrode T5E1 and the second electrode T5E2.

The fifth bottom metal layer BML2 may be located under the fifth channel portion T5CH.

The fifth bottom metal layer BML2 may be a bottom metal layer BML that blocks light traveling from under the display device toward the fifth channel portion T5CH.

The second transistor T2 may include the active layer ACT202 of the second transistor T2 (or an active layer of the third transistor T3) and the gate electrode GAT303 of the second transistor T2.

The active layer ACT202 of the second transistor T2 (or the active layer of the third transistor T3) may include a first electrode of the second transistor T2, a second electrode of the second transistor T2, and a second channel portion formed between the first electrode and the second electrode.

The third transistor T3 may include the active layer ACT202 of the second transistor T2 (or the active layer of the third transistor T3) and the gate electrode GAT303 of the second transistor T2.

The active layer ACT202 of the second transistor T2 (or the active layer of the third transistor T3) may include a first electrode of the third transistor T3, a second electrode of the third transistor T3, and a third channel portion formed between the first electrode and the second electrode.

The second electrode ACT101 of the first capacitor C11 may have conductivity as a doped first semiconductor layer ACT100 and may function as an electrode or a connection electrode.

The first electrode ACT203 of the third capacitor C21 and the first electrode ACT204 of the fourth capacitor C22 may each have conductivity as a doped second semiconductor layer ACT200 and may each function as an electrode or a connection electrode.

The first group capacitor C1 may include the first capacitor C11 and the second capacitor C12 connected in parallel.

The first capacitor C11 may include the first electrode BML1 of the first capacitor C11 and the second electrode ACT101 of the first capacitor C11.

The second capacitor C12 may include the first electrode GAT101 of the second capacitor C12 and the second electrode ACT101 of the first capacitor C11.

The second group capacitor C2 may include the third capacitor C21, the fourth capacitor C22, the fifth capacitor C23, and the sixth capacitor C24 connected in parallel.

The third capacitor C21 may include the first electrode ACT203 of the third capacitor C21 and the second electrode GAT202 of the third capacitor C21.

The fourth capacitor C22 may include the first electrode ACT204 of the fourth capacitor C22 and the second electrode GAT202 of the third capacitor C21.

The fifth capacitor C23 may include the first electrode GAT102 of the fifth capacitor C23 and the second electrode GAT202 of the third capacitor C21.

The sixth capacitor C24 may include the first electrode GAT102 of the fifth capacitor C23 and the second electrode ACT101 of the first capacitor C11.

A plurality of contact holes may include first through seventeenth contact holes CH1 through CH17.

The first contact hole CH1 may electrically connect the bottom gate electrode GAT201 of the first transistor T1 and the second connection electrode SD101.

The second contact hole CH2 may electrically connect the gate electrode GAT301 of the first transistor T1 and the third connection electrode SD102.

The third contact hole CH3 may electrically connect the first electrode GAT101 of the second capacitor C12 and the third connection electrode SD102.

The fourth contact hole CH4 may electrically connect the first electrode BML1 of the first capacitor C11 and the third connection electrode SD102.

The fifth contact hole CH5 may electrically connect the second electrode ACT101 of the first capacitor C11 and the first anode connection electrode SD103.

The sixth contact hole CH6 may electrically connect the active layer ACT201 of the first transistor T1 and the first anode connection electrode SD103.

The seventh contact hole CH7 may electrically connect the active layer ACT201 of the first transistor T1 and the fifth connection electrode SD104.

The eighth contact hole CH8 may electrically connect the active layer ACT102 of the fifth transistor T5 and the fifth connection electrode SD104.

The ninth contact hole CH9 may electrically connect the second electrode GAT202 of the third capacitor C21 and the first connection electrode GAT302.

The tenth contact hole CH10 may electrically connect the second electrode ACT101 of the first capacitor C11 and the first connection electrode GAT302.

The eleventh contact hole CH11 may electrically connect the first electrode ACT203 of the third capacitor C21 and the sixth connection electrode SD105.

The twelfth contact hole CH12 may electrically connect the first electrode ACT204 of the fourth capacitor C22 and the sixth connection electrode SD105.

The thirteenth contact hole CH13 may electrically connect the first electrode GAT102 of the fifth capacitor C23 and the sixth connection electrode SD105.

The fourteenth contact hole CH14 may electrically connect the seventh connection electrode SD201 and the sixth connection electrode SD105.

The fifteenth contact hole CH15 may electrically connect the active layer ACT102 of the fifth transistor T5 and the sixth connection electrode SD105.

The sixteenth contact hole CH16 may electrically connect the second connection electrode SD101 and the eighth connection electrode SD202.

The seventeenth contact hole CH17 may electrically connect the active layer ACT202 of the second transistor T2 (or the active layer of the third transistor T3) and the third connection electrode SD102.

The first electrode BML1 of the first capacitor C11 may be connected to the gate electrode node of the first transistor T1.

The second electrode ACT101 of the first capacitor C11 may be connected to the first electrode node of the first transistor T1.

The active layer ACT102 of the fifth transistor T5 may include the first electrode T5E1 of the fifth transistor T5, the second electrode T5E2 of the fifth transistor T5, and the fifth channel portion T5CH formed between the first electrode T5E1 and the second electrode T5E2.

The first electrode GAT101 of the second capacitor C12 may be connected to the gate electrode node of the first transistor T1.

The first electrode GAT102 of the fifth capacitor C23 may be connected to the first driving voltage node.

The gate electrode GAT103 of the fifth transistor T5 may be connected to a gate electrode node of the fifth transistor T5.

The bottom gate electrode GAT201 of the first transistor T1 may be connected to a third driving voltage node.

The second electrode GAT202 of the third capacitor C21 may be connected to the first electrode node of the first transistor T1.

The active layer ACT201 of the first transistor T1 may include the first electrode T1E1 of the first transistor T1, the second electrode T1E2 of the first transistor T1, and the first channel portion T1CH formed between the first electrode T1E1 and the second electrode T1E2.

The active layer ACT202 of the second transistor T2 (or the active layer of the third transistor T3) may include the first electrode of the second transistor T2, the second electrode of the second transistor T2, and the second channel portion formed between the first electrode and the second electrode.

In addition, the active layer ACT202 of the second transistor T2 (or the active layer of the third transistor T3) may include the first electrode of the third transistor T3, the second electrode of the third transistor T3, and the third channel portion formed between the first electrode and the second electrode.

The second electrode of the second transistor T2 may be connected to the first electrode of the third transistor T3.

The first electrode ACT203 of the third capacitor C21 may be connected to the first driving voltage node.

The first electrode ACT204 of the fourth capacitor C22 may be connected to the first driving voltage node.

The gate electrode GAT301 of the first transistor T1 may be connected to the gate electrode node of the first transistor T1.

The first connection electrode GAT302 may be connected to the first electrode node of the first transistor T1.

The gate electrode GAT303 of the second transistor T2 may be connected to the gate electrode node of the second transistor T2.

The gate electrode GAT304 of the third transistor T3 may be connected to the gate electrode node of the third transistor T3.

The second connection electrode SD101 may be connected to the third driving voltage node.

The third connection electrode SD102 may be connected to the gate electrode node of the first transistor T1.

The first anode connection electrode SD103 may be connected to the first electrode node of the first transistor T1.

The fifth connection electrode SD104 may be connected to the second electrode node of the first transistor T1.

The sixth connection electrode SD105 may be connected to the first driving voltage node.

The seventh connection electrode SD201 may be connected to the first driving voltage node.

The eighth connection electrode SD202 may be connected to the third driving voltage node.

The second anode connection electrode SD203 may be connected to an anode node of the light emitting element LE.

As described above, being electrically connected is a concept that includes being indirectly connected by another layer.

Referring to FIG. 30, the fifth transistor T5 may include the active layer ACT102 of the fifth transistor T5 and the gate electrode GAT103 of the fifth transistor T5. The active layer ACT102 of the fifth transistor T5 may include the first electrode T5E1 of the fifth transistor T5, the second electrode T5E2 of the fifth transistor T5, and the fifth channel portion T5CH located between the first electrode T5E1 of the fifth transistor T5 and the second electrode T5E2 of the fifth transistor T5. The fifth channel portion T5CH may overlap the gate electrode GAT103 of the fifth transistor T5 in the thickness direction of the substrate 110. The fifth bottom metal layer BML2 may overlap the fifth channel portion T5CH in the thickness direction of the substrate 110 (e.g., the third direction DR3). The fifth bottom metal layer BML2 may be a bottom metal layer BML that blocks light traveling from under the display device toward the fifth channel portion T5CH.

The fifth transistor T5 may be implemented as a p-channel transistor. In this case, the first electrode T5E1 of the fifth transistor T5 may be connected to the first driving voltage node. However, the present specification is not limited to this case. The active layer ACT102 of the fifth transistor T5 may be electrically connected to the seventh connection electrode SD201 by the fifteenth contact hole CH15. The seventh connection electrode SD201 may be connected to the first driving voltage node in response to the first driving voltage ELVDD applied to the seventh connection electrode SD201. Therefore, the active layer ACT102 of the fifth transistor T5 may be connected to the first driving voltage node by the fifteenth contact hole CH15.

Referring to FIG. 27, the fifth transistor T5 may be implemented as a p-channel transistor. In this case, the second electrode T5E2 of the fifth transistor T5 may be connected to the second electrode T1E2 of the first transistor T1. The active layer ACT102 of the fifth transistor T5 may be electrically connected to the active layer ACT201 of the first transistor T1. The active layer ACT102 of the fifth transistor T5 may be electrically connected to the fifth connection electrode SD104 by the eighth contact hole CH8. The active layer ACT201 of the first transistor T1 may be electrically connected to the fifth connection electrode SD104 by the seventh contact hole CH7. Therefore, the active layer ACT102 of the fifth transistor T5 may be electrically connected to the active layer ACT201 of the first transistor T1 by the seventh contact hole CH7 and the eighth contact hole CH8.

Referring to FIG. 26, the third driving voltage TUN may be applied to the bottom gate electrode GAT201 of the first transistor T1. The bottom gate electrode GAT201 of the first transistor T1 may be electrically connected to the second connection electrode SD101 by the first contact hole CH1. The second connection electrode SD101 may be electrically connected to the eighth connection electrode SD202 by the sixteenth contact hole CH16. The eighth connection electrode SD202 may be connected to the third driving voltage node in response to the third driving voltage TUN applied to the eighth connection electrode SD202. Therefore, the bottom gate electrode GAT201 of the first transistor T1 may be connected to the third driving voltage node and may receive the third driving voltage TUN.

Referring to FIG. 27, the first transistor T1 may include the active layer ACT201 of the first transistor T1 and the gate electrode GAT301 of the first transistor T1. The active layer ACT201 of the first transistor T1 may include the first electrode T1E1 of the first transistor T1, the second electrode T1E2 of the first transistor T1, and the first channel portion T1CH located between the first electrode T1E1 of the first transistor T1 and the second electrode T1E2 of the first transistor T1. The first channel portion T1CH may overlap the gate electrode GAT301 of the first transistor T1 in the thickness direction of the substrate 110 (e.g., the third direction DR3). The bottom gate electrode GAT201 of the first transistor T1 may overlap the active layer ACT201 of the first transistor T1 in the thickness direction of the substrate 110 (e.g., the third direction DR3). The gate electrode GAT301 of the first transistor T1 may apply a first gate voltage to the active layer ACT201 of the first transistor T1. The bottom gate electrode GAT201 of the first transistor T1 may apply the second gate voltage to the active layer ACT201 of the first transistor T1. As described above, the third driving voltage TUN may be applied as the second gate voltage to the first transistor T1. To this end, the bottom gate electrode GAT201 of the first transistor T1, which was previously connected to the first electrode node of the first transistor T1, needs to be separated from the second electrode GAT202 of the third capacitor C21.

Referring to FIG. 26, the first electrode BML1 of the first capacitor C11 may be electrically connected to the gate electrode GAT301 of the first transistor T1. The first electrode BML1 of the first capacitor C11 may be electrically connected to the third connection electrode SD102 by the fourth contact hole CH4. The gate electrode GAT301 of the first transistor T1 may be electrically connected to the third connection electrode SD102 by the second contact hole CH2. Therefore, the first electrode BML1 of the first capacitor C11 may be electrically connected to the gate electrode GAT301 of the first transistor T1 and may be connected to the gate electrode node of the first transistor T1.

Referring to FIG. 27, the second electrode ACT101 of the first capacitor C11 may be electrically connected to the active layer ACT201 of the first transistor T1. Specifically, the second electrode ACT101 of the first capacitor C11 may be electrically connected to the first electrode T1E1 of the first transistor T1. The second electrode ACT101 of the first capacitor C11 may be electrically connected to the first anode connection electrode SD103 by the fifth contact hole CH5. The first electrode T1E1 of the first transistor T1 may be electrically connected to the first anode connection electrode SD103 by the sixth contact hole CH6. Therefore, the second electrode ACT101 of the first capacitor C11 may be electrically connected to the first electrode T1E1 of the first transistor T1 and may be connected to the first electrode node of the first transistor T1.

The first electrode BML1 of the first capacitor C11 that is connected to the gate electrode node of the first transistor T1 and the second electrode ACT101 of the first capacitor C11 that is connected to the first electrode node of the first transistor T1 may overlap in the thickness direction of the substrate 110 (e.g., the third direction DR3) to form the first capacitor C11. one or more embodiments of the present disclosure may can improve the problem of insufficient capacity of the first group capacitor C1 by additionally placing the first electrode BML1 of the first capacitor C11 which is connected to the gate electrode node of the first transistor T1.

Referring to FIG. 26, the first electrode GAT101 of the second capacitor C12 may be electrically connected to the gate electrode GAT301 of the first transistor T1. The gate electrode GAT301 of the first transistor T1 may be electrically connected to the third connection electrode SD102 by the second contact hole CH2. The first electrode GAT101 of the second capacitor C12 may be electrically connected to the third connection electrode SD102 by the third contact hole CH3. Therefore, the first electrode GAT101 of the second capacitor C12 may be electrically connected to the gate electrode GAT301 of the first transistor T1 and may be connected to the gate electrode node of the first transistor T1.

Referring to FIG. 27, the second electrode ACT101 of the first capacitor C11 may be electrically connected to the active layer ACT201 of the first transistor T1. Specifically, the second electrode ACT101 of the first capacitor C11 may be electrically connected to the first electrode T1E1 of the first transistor T1. The second electrode ACT101 of the first capacitor C11 may be electrically connected to the first anode connection electrode SD103 by the fifth contact hole CH5. The first electrode T1E1 of the first transistor T1 may be electrically connected to the first anode connection electrode SD103 by the sixth contact hole CH6. Therefore, the second electrode ACT101 of the first capacitor C11 may be electrically connected to the first electrode T1E1 of the first transistor T1 and may be connected to the first electrode node of the first transistor T1.

The first electrode GAT101 of the second capacitor C12 that is connected to the gate electrode node of the first transistor T1 and the second electrode ACT101 of the first capacitor C11 that is connected to the first electrode node of the first transistor T1 may overlap in the thickness direction of the substrate 110 (e.g., the third direction DR3) to form the second capacitor C12.

Referring to FIG. 28, the second electrode GAT202 of the third capacitor C21 that is separated from the bottom gate electrode GAT201 of the first transistor T1 may be electrically connected to the second electrode ACT101 of the first capacitor C11 by the first connection electrode GAT302. The second electrode GAT202 of the third capacitor C21 may be electrically connected to the first connection electrode GAT302 by the ninth contact hole CH9. The second electrode ACT101 of the first capacitor C11 may be electrically connected to the first connection electrode GAT302 by the tenth contact hole CH10. Therefore, the second electrode GAT202 of the third capacitor C21 may be electrically connected to the second electrode ACT101 of the first capacitor C11 and may be connected to the first electrode node of the first transistor T1.

Referring to FIG. 30, the seventh connection electrode SD201 that is connected to the first driving voltage node may be electrically connected to the first electrode GAT102 of the fifth capacitor C23. The first electrode GAT102 of the fifth capacitor C23 may be electrically connected to the sixth connection electrode SD105 by the thirteenth contact hole CH13. The seventh connection electrode SD201 may be electrically connected to the sixth connection electrode SD105 by the fourteenth contact hole CH14. Therefore, the seventh connection electrode SD201 may be electrically connected to the first electrode GAT102 of the fifth capacitor C23, and the first electrode GAT102 of the fifth capacitor C23 may be connected to the first driving voltage node.

Referring to FIG. 28, the first electrode GAT102 of the fifth capacitor C23 that is connected to the first driving voltage node and the second electrode GAT202 of the third capacitor C21 that is connected to the first electrode node of the first transistor T1 may overlap in the thickness direction of the substrate 110 (e.g., the third direction DR3) to form the fifth capacitor C23. The second electrode GAT202 of the third capacitor C21 may be separated from the bottom gate electrode GAT201 of the first transistor T1 as the bottom gate electrode GAT201 of the first transistor T1 is electrically connected (see FIG. 26) to the third driving voltage node to which the third driving voltage TUN is applied. In one or more embodiments, the first connection electrode GAT302 may be additionally placed (see FIG. 28) to connect the second electrode GAT202 of the third capacitor C21 to the first electrode node of the first transistor T1 (see FIG. 28). As described above, even when the bottom gate electrode GAT201 of the first transistor T1 and the second electrode GAT202 of the third capacitor C21 are separated, the second electrode GAT202 of the third capacitor C21 may still be connected to the first electrode node of the first transistor T1 by the first connection electrode GAT302. Therefore, according to one or more embodiments, the fifth capacitor C23, which exists in the conventional art, can be maintained, and thus the capacity of the second group capacitor C2 can be maintained.

Referring to FIG. 27, the second electrode ACT101 of the first capacitor C11 may be electrically connected to the active layer ACT201 of the first transistor T1. Specifically, the second electrode ACT101 of the first capacitor C11 may be electrically connected to the first electrode T1E1 of the first transistor T1. The second electrode ACT101 of the first capacitor C11 may be electrically connected to the first anode connection electrode SD103 by the fifth contact hole CH5. The first electrode T1E1 of the first transistor T1 may be electrically connected to the first anode connection electrode SD103 by the sixth contact hole CH6. Therefore, the second electrode ACT101 of the first capacitor C11 may be electrically connected to the first electrode T1E1 of the first transistor T1 and may be connected to the first electrode node of the first transistor T1.

Referring to FIG. 30, the seventh connection electrode SD201 that is connected to the first driving voltage node may be electrically connected to the first electrode GAT102 of the fifth capacitor C23. The first electrode GAT102 of the fifth capacitor C23 may be electrically connected to the sixth connection electrode SD105 by the thirteenth contact hole CH13. The seventh connection electrode SD201 may be electrically connected to the sixth connection electrode SD105 by the fourteenth contact hole CH14. Therefore, the seventh connection electrode SD201 may be electrically connected to the first electrode GAT102 of the fifth capacitor C23, and the first electrode GAT102 of the fifth capacitor C23 may be connected to the first driving voltage node.

Referring to FIG. 29, the second electrode ACT101 of the first capacitor C11 that is connected to the first electrode node of the first transistor T1 and the first electrode GAT102 of the fifth capacitor C23 that is connected to the first driving voltage node overlap in the thickness direction of the substrate 110 (e.g., the third direction DR3) to form the sixth capacitor C24.

Referring to FIGS. 29 and 30, the seventh connection electrode SD201 that is connected to the first driving voltage node may be connected to the first electrode ACT203 of the third capacitor C21 and the first electrode ACT204 of the fourth capacitor C22. The first electrode ACT203 of the third capacitor C21 may be electrically connected to the sixth connection electrode SD105 by the eleventh contact hole CH11. In addition, the first electrode ACT204 of the fourth capacitor C22 may be electrically connected to the sixth connection electrode SD105 by the twelfth contact hole CH12. The seventh connection electrode SD201 may be electrically connected to the sixth connection electrode SD105 by the fourteenth contact hole CH14. Therefore, the seventh connection electrode SD201 that is connected to the first driving voltage node may be electrically connected to the first electrode ACT203 of the third capacitor C21 and the first electrode ACT204 of the fourth capacitor C22, and the first electrode ACT203 of the third capacitor C21 and the first electrode ACT204 of the fourth capacitor C22 may be connected to the first driving voltage node.

Referring to FIG. 28, the second electrode GAT202 of the third capacitor C21 that is separated from the bottom gate electrode GAT201 of the first transistor T1 may be electrically connected to the second electrode ACT101 of the first capacitor C11 by the first connection electrode GAT302. The second electrode GAT202 of the third capacitor C21 may be electrically connected to the first connection electrode GAT302 by the ninth contact hole CH9. The second electrode ACT101 of the first capacitor C11 may be electrically connected to the first connection electrode GAT302 by the tenth contact hole CH10. Therefore, the second electrode GAT202 of the third capacitor C21 may be electrically connected to the second electrode ACT101 of the first capacitor C11 and may be connected to the first electrode node of the first transistor T1.

Therefore, the second electrode GAT202 of the third capacitor C21 that is connected to the first electrode node of the first transistor T1 may form the third capacitor C21 and the fourth capacitor C22 with the first electrode ACT203 of the third capacitor C21 and the first electrode ACT204 of the fourth capacitor C22, which are connected to the first driving voltage node, respectively.

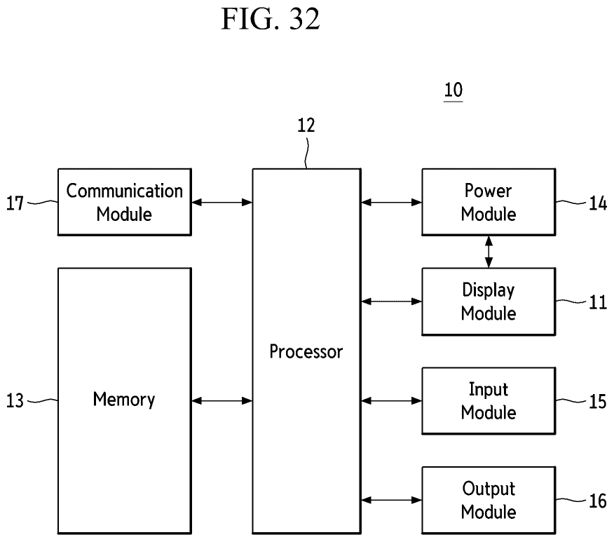

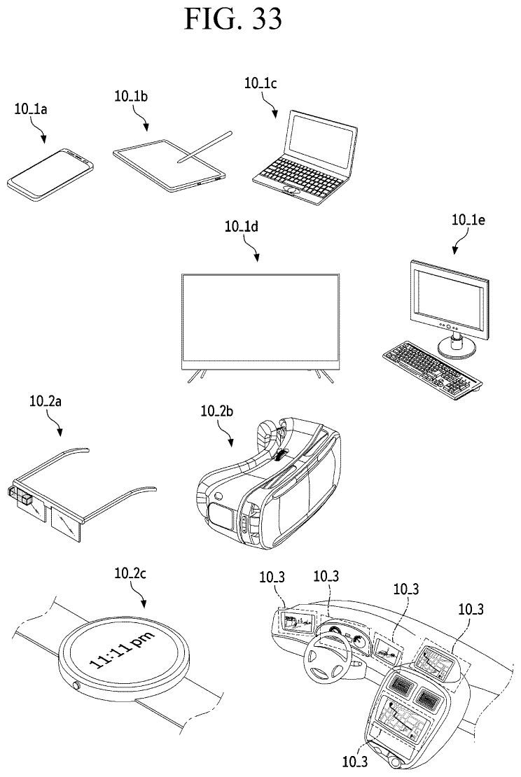

FIG. 32 is a block diagram of an electronic device according to an embodiment of the present specification. FIG. 33 is a schematic diagram of electronic devices according to various embodiments of the present specification.

Referring to FIG. 32, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power necessary for the operation of the electronic device 10 by converting power supplied by the power supply module.

At least one of the elements of the electronic device 10 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 10.

Referring to FIG. 33, various electronic devices to which a display device according to embodiments of the present specification is applied may include image display electronic devices such as a smartphone 10_1a, a tablet PC 10_1b, a laptop 10_1c, a television 10_1d, and a desk monitor 10_1e. In addition, the various electronic devices to which the display device according to the embodiments of the present specification is applied may include wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument cluster, center fascia and dashboard of a vehicle.

Although embodiments of the present disclosure have been described above with reference to the accompanying drawings, it will be understood by those having ordinary skill in the technical field to which the present disclosure belongs that the present disclosure may be practiced in other specific forms without altering the technical idea or essential features of the present disclosure. It should therefore be understood that the embodiments described above are examples in all respects and are not intended to be limiting.

What is claimed is:

1. A display device comprising:
a substrate;
a bottom metal layer located on the substrate and comprising a first electrode of a first capacitor;
a second semiconductor layer located on the bottom metal layer and comprising an active layer of a first transistor; and
a third gate metal layer located on the second semiconductor layer and comprising a gate electrode of the first transistor,
wherein the active layer of the first transistor comprises a first electrode of the first transistor, a second electrode of the first transistor, and a first channel portion located between the first electrode of the first transistor and the second electrode of the first transistor, and the first electrode of the first capacitor is electrically connected to the gate electrode of the first transistor.

2. The display device of claim 1, further comprising a first semiconductor layer located between the bottom metal layer and the second semiconductor layer and comprising a second electrode of the first capacitor, wherein the second electrode of the first capacitor is electrically connected to the first electrode of the first transistor, and the second electrode of the first capacitor overlaps the first electrode of the first capacitor in a thickness direction of the substrate.

3. The display device of claim 2, further comprising a first gate metal layer located between the first semiconductor layer and the second semiconductor layer and comprising a first electrode of a second capacitor, wherein the first electrode of the second capacitor is electrically connected to the gate electrode of the first transistor, and the first electrode of the second capacitor overlaps the second electrode of the first capacitor in the thickness direction of the substrate.

4. The display device of claim 1, further comprising:
a first semiconductor layer located between the bottom metal layer and the second semiconductor layer and comprising a second electrode of the first capacitor; and
a second gate metal layer located between the first semiconductor layer and the second semiconductor layer and comprising a second electrode of a third capacitor,
wherein the second electrode of the third capacitor is electrically connected to the first electrode of the first transistor.

5. The display device of claim 4, wherein the second electrode of the first capacitor is electrically connected to the second electrode of the third capacitor.

6. The display device of claim 5, wherein the third gate metal layer further comprises a first connection electrode, and the first connection electrode is electrically connected to the second electrode of the first capacitor and the second electrode of the third capacitor.

7. The display device of claim 4, wherein the second semiconductor layer further comprises a first electrode of the third capacitor and a first electrode of a fourth capacitor, a first driving voltage is applied to the first electrode of the third capacitor and the first electrode of the fourth capacitor, the second electrode of the third capacitor overlaps the first electrode of the third capacitor in a thickness direction of the substrate, and the second electrode of the third capacitor overlaps the first electrode of the fourth capacitor in the thickness direction of the substrate.

8. The display device of claim 4, further comprising a first gate metal layer located between the first semiconductor layer and the second gate metal layer and comprising a first electrode of a fifth capacitor, wherein a first driving voltage is applied to the first electrode of the fifth capacitor, and the second electrode of the third capacitor overlaps the first electrode of the fifth capacitor in a thickness direction of the substrate.

9. The display device of claim 8, wherein the second electrode of the first capacitor overlaps the first electrode of the fifth capacitor in the thickness direction of the substrate.

10. The display device of claim 1, further comprising a first semiconductor layer located between the bottom metal layer and the second semiconductor layer and comprising an active layer of a fifth transistor, wherein the active layer of the fifth transistor further comprises a first electrode of the fifth transistor to which a first driving voltage is applied, a second electrode of the fifth transistor and a fifth channel portion located between the first electrode of the fifth transistor and the second electrode of the fifth transistor, and the bottom metal layer further comprises a fifth bottom metal layer overlapping the fifth channel portion in a thickness direction of the substrate.

11. The display device of claim 10, wherein the second electrode of the fifth transistor is electrically connected to the second electrode of the first transistor through a plurality of contact holes.

12. The display device of claim 10, wherein the first semiconductor layer further comprises a first electrode of a fifth capacitor, and the first electrode of the fifth transistor is electrically connected to the first electrode of the fifth capacitor through a plurality of contact holes.

13. The display device of claim 1, further comprising:
a first semiconductor layer located between the bottom metal layer and the second semiconductor layer; and
a second gate metal layer located between the first semiconductor layer and the second semiconductor layer and comprising a bottom gate electrode of the first transistor,
wherein the bottom gate electrode of the first transistor overlaps the active layer of the first transistor in a thickness direction of the substrate.

14. The display device of claim 13, wherein the gate electrode of the first transistor is configured to supply a first gate voltage to the first transistor, and the bottom gate electrode of the first transistor is configured to supply a second gate voltage to the first transistor.

15. The display device of claim 14, wherein a third driving voltage is applied to the bottom gate electrode of the first transistor which is configured to supply the second gate voltage, and a driving current curve of the first transistor shifts as the third driving voltage is changed.

16. An electronic device comprising:
a processor configured to provide an image signal;
a display module configured to receive the image signal from the processor and display an image; and
a power module configured to supply power to the display module,
wherein the display module comprises:
a substrate;
a bottom metal layer located on the substrate and comprising a first electrode of a first capacitor;
a second semiconductor layer located on the bottom metal layer and comprising an active layer of a first transistor; and
a third gate metal layer located on the second semiconductor layer and comprising a gate electrode of the first transistor,
wherein the active layer of the first transistor comprises a first electrode of the first transistor, a second electrode of the first transistor, and a first channel portion located between the first electrode of the first transistor and the second electrode of the first transistor, and the first electrode of the first capacitor is electrically connected to the gate electrode of the first transistor.

17. The electronic device of claim 16, further comprising a first semiconductor layer located between the bottom metal layer and the second semiconductor layer and comprising a second electrode of the first capacitor, wherein the second electrode of the first capacitor is electrically connected to the first electrode of the first transistor, and the second electrode of the first capacitor overlaps the first electrode of the first capacitor in a thickness direction of the substrate.

18. The electronic device of claim 16, further comprising:
a first semiconductor layer located between the bottom metal layer and the second semiconductor layer and comprising a second electrode of the first capacitor; and
a second gate metal layer located between the first semiconductor layer and the second semiconductor layer and comprising a second electrode of a third capacitor,
wherein the second electrode of the third capacitor is electrically connected to the first electrode of the first transistor.

19. The electronic device of claim 16, further comprising a first semiconductor layer located between the bottom metal layer and the second semiconductor layer and comprising an active layer of a fifth transistor, wherein the active layer of the fifth transistor further comprises a first electrode of the fifth transistor to which a first driving voltage is applied, a second electrode of the fifth transistor, and a fifth channel portion located between the first electrode of the fifth transistor and the second electrode of the fifth transistor, and the bottom metal layer further comprises a fifth bottom metal layer overlapping the fifth channel portion in a thickness direction of the substrate.

20. The electronic device of claim 16, further comprising:
a first semiconductor layer located between the bottom metal layer and the second semiconductor layer; and
a second gate metal layer located between the first semiconductor layer and the second semiconductor layer and comprising a bottom gate electrode of the first transistor,
wherein the bottom gate electrode of the first transistor overlaps the active layer of the first transistor in a thickness direction of the substrate.
